(19) United States
(12) Patent Application Publication
(10) Pub. No.: US 2026/0353661 A1
(43) Pub. Date: Nov. 5, 2026

(54) SEMICONDUCTOR DEVICE WITH COMMON GATE STRUCTURE AND ELECTRONIC SYSTEM INCLUDING THE SAME

(71) Applicant: Samsung Electronics Co., Ltd., Suwon-si (KR)

(72) Inventors: Hakseon Kim, Suwon-si (KR); Sejun Park, Suwon-si (KR); Seahoon Lee, Suwon-si (KR); Seongpil Chang, Suwon-si (KR)

(21) Appl. No.: 19/656,650

(22) Filed: Apr. 23, 2026

(30) Foreign Application Priority Data
Apr. 30, 2025 (KR) 10-2025-0057764

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device includes a substrate including a plurality of active regions defined by a device isolation layer. Each of the plurality of active regions includes a central region and a first main active region and a second main active region extending from the central region and spaced apart from each other in a first horizontal direction. The plurality of active regions include a first active region and a second active region adjacent to each other in the first horizontal direction, a first gate structure on the first main active region of the first active region, and a second gate structure on the second main active region of the first active region and the first main active region of the second active region. The second gate structure is spaced apart from the first gate structure.

### CROSS-REFERENCE TO RELATED APPLICATION

This application claims the benefit of an earlier filing date and right of priority under 35 U.S.C. § 119(a) to Korean Patent Application No. 10-2025-0057764, filed on Apr. 30, 2025, in the Korean Intellectual Property Office, the disclosure of which is incorporated by reference herein in its entirety.

### BACKGROUND

In an electronic system requiring data storage, semiconductor devices capable of storing high capacity data have been needed. As a method of increasing the data storage capacity of a semiconductor device, a semiconductor device including three-dimensionally arranged memory cells, rather than two-dimensionally arranged memory cells, has been introduced.

### SUMMARY

The disclosure provides a semiconductor device having improved operation characteristics and improved integration.

According to an aspect of the disclosure, there is provided a semiconductor device including a substrate including a plurality of active regions defined by a device isolation layer, wherein each of the plurality of active regions includes a central region, a first main active region and a second main active region extending from the central region and spaced apart from each other in a first horizontal direction, and a third main active region and a fourth main active region extending from the central region, spaced apart from each other in the first horizontal direction, and spaced apart from the first main active region and the second main active region in a second horizontal direction, and the plurality of active regions include a first active region and a second active region adjacent to each other in the first horizontal direction, a first gate structure on the first main active region of the first active region, and a second gate structure on the second main active region of the first active region and the first main active region of the second active region and spaced apart from the first gate structure.

According to another aspect of the disclosure, there is provided a semiconductor device including a substrate including a plurality of active regions defined by a device isolation layer, wherein each of the plurality of active regions includes a central region, a first main active region and a second main active region extending from the central region and spaced apart from each other in a first horizontal direction, and a third main active region and a fourth main active region extending from the central region and spaced apart from the first main active region and the second main active region in a second horizontal direction, and a plurality of gate structures overlapping portions of two adjacent active regions from among the plurality of active regions and extending in the first horizontal direction, the plurality of gate structures including a first gate structure on the first main active region of a first active region, a second gate structure on the second main active region of the first active region and the first main active region of a second active region, a third gate structure on the third main active region of the first active region, and a fourth gate structure on the fourth main active region of the first active region and the third main active region of the second active region.

According to another aspect of the disclosure, there is provided a semiconductor device including a substrate including a plurality of active regions, wherein each of the plurality of active regions includes a central region, a first main active region and a second main active region extending from the central region and spaced apart from each other in a first horizontal direction, and a third main active region and a fourth main active region extending from the central region and spaced apart from the first main active region and the second active region in a second horizontal direction, a device isolation layer on the substrate and defining the plurality of active regions, wherein the device isolation layer includes a first portion between two adjacent active regions from among the plurality of active regions and a second portion between the first main active region and the second main active region of each of the plurality of active regions and between the third main active region and the fourth main active region of each of the plurality of active regions, a plurality of gate structures overlapping portions of two adjacent active regions from among the plurality of active regions and extending in the first horizontal direction, wherein the plurality of gate structures include a first gate structure on the first main active region of a first active region, a second gate structure on the second main active region of the first active region and the first main active region of a second active region, a third gate structure on the third main active region of the first active region, and a fourth gate structure on the fourth main active region of the first active region and the third main active region of the second active region, and a drain contact on the central region and surrounded by the first to fourth gate structures in a plan view.

According to another aspect of the disclosure, there is provided a semiconductor device including a substrate including a plurality of active regions, wherein each of the plurality of active regions includes a central region, a first main active region and a second main active region extending from the central region and spaced apart from each other in a first horizontal direction, and a third main active region and a fourth main active region extending from the central region and spaced apart from the first main active region and the second active region in a second horizontal direction, a device isolation layer on the substrate and defining the plurality of active regions, wherein the device isolation layer includes a first portion between two adjacent active regions from among the plurality of active regions, a second portion between the first main active region and the second main active region of each of the plurality of active regions and between the third main active region and the fourth main active region of each of the plurality of active regions, and a third portion integrally connected to the second portion and at least partially surrounded by the central region in a plan view, a first gate structure on the first main active region, and a field plate electrode electrically connected to the first gate structure and including a first conductive layer portion to vertically overlap the first gate structure and a second conductive layer portion integrally connected to the first conductive layer portion and vertically overlapping the third portion of the device isolation layer.

According to implementations, the second portion of the device isolation layer may have a first width in the first horizontal direction, and the third portion of the device isolation layer may have a second width that is greater than the first width in the first horizontal direction.

According to implementations, the second conductive layer portion may not vertically overlap the central region or the first main active region.

According to implementations, the semiconductor device may further include a second gate structure on the second main active region, a third gate structure on the third main active region, and a fourth gate structure on the fourth main active region.

According to implementations, the semiconductor device may further include an insulating layer on the substrate and covering the first to fourth gate structures and a first gate contact passing through the insulating layer and between the first gate structure and the field plate electrode.

According to implementations, the semiconductor device may further include a drain contact passing through the insulating layer and on the central region, and the drain contact may be surrounded by the first to fourth gate structures in a plan view.

According to implementations, the substrate may further include a first source region in the first main active region and in a plan view, at a side of the first gate structure, a second source region in the second main active region and in a plan view, at a side of the second gate structure, a third source region in the third main active region and in a plan view, at a side of the third gate structure, and a fourth source region in the fourth main active region and in a plan view, at a side of the fourth gate structure.

According to implementations, each of the plurality of active regions may have an H shape in a plan view.

According to implementations, the semiconductor device may further include a cell array region on the substrate, wherein the cell array region may include a plurality of word lines spaced apart from each other in a vertical direction, a plurality of channels passing through the plurality of word lines and extending in the vertical direction, and a cell contact connected to any one of the plurality of word lines, and the cell contact may be electrically connected to any one of the plurality of active regions.

According to implementations, the cell array region may include a plurality of memory blocks, the first main active region of the first active region may be electrically connected to a first word line included in a first memory block from among the plurality of memory blocks, the second main active region of the first active region may be electrically connected to a first word line included in a second memory block from among the plurality of memory blocks, the third main active region may be electrically connected to a first word line included in a third memory block from among the plurality of memory blocks, and the fourth main active region may be electrically connected to a first word line included in a fourth memory block from among the plurality of memory blocks.

### BRIEF DESCRIPTION OF THE DRAWINGS

Implementations will be more clearly understood from the following detailed description taken in conjunction with the accompanying drawings.

FIG. 1 is a block diagram of a semiconductor device according to implementations.

FIG. 2 is a schematic perspective view of a semiconductor device according to implementations.

FIG. 3 is a schematic view of a pass transistor circuit according to implementations.

FIG. 4 is a circuit diagram of a memory block according to implementations.

FIG. 5 is a layout diagram of a pass transistor included in a semiconductor device according to implementations.

FIG. 6 is an enlarged layout diagram of region EN1 of FIG. 5.

FIG. 7 is a cross-sectional view of the semiconductor device taken along line A-A′ of FIG. 6.

FIG. 8 is a cross-sectional view of the semiconductor device taken alone line B-B′ of FIG. 6.

FIG. 9 is a cross-sectional view of the semiconductor device taken along line C-C′ of FIG. 6.

FIG. 10 is a cross-sectional view of a semiconductor device according to implementations.

FIG. 11 is a layout diagram of a pass transistor included in a semiconductor device according to implementations.

FIG. 12 is an enlarged layout diagram of region EN1 of FIG. 11.

FIG. 13 is an enlarged layout diagram of region EN2 of FIG. 12.

FIG. 14 is a cross-sectional view of the semiconductor device taken along line A-A′ of FIG. 12.

FIG. 15 is a cross-sectional view of the semiconductor device taken along line B-B′ of FIG. 12.

FIG. 16 is a layout diagram of a semiconductor device according to implementations.

FIG. 17 is a layout diagram of a semiconductor device according to implementations.

FIG. 18 is a layout diagram of a semiconductor device according to implementations.

FIG. 19 is a cross-sectional view of a semiconductor device according to implementations.

FIG. 20 is a cross-sectional view of a semiconductor device according to implementations.

FIG. 21 is a schematic view of a data storage system including a semiconductor device according to implementations.

FIG. 22 is a schematic perspective view of a data storage system including a semiconductor device according to implementations.

FIG. 23 is a schematic cross-sectional view of semiconductor packages according to implementations.

### DETAILED DESCRIPTION

Hereinafter, implementations will be described in detail by referring to the accompanying drawings.

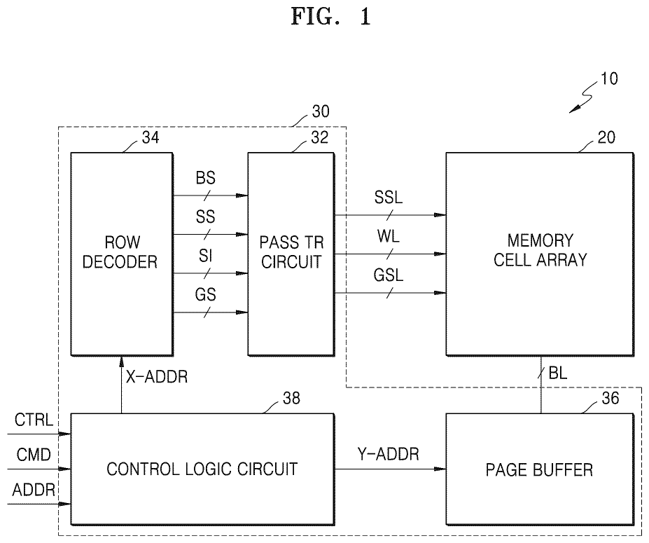

FIG. 1 is a block diagram of a semiconductor device 10 according to implementations.

Referring to FIG. 1, the semiconductor device 10 may include a memory cell array 20 and a peripheral circuit 30.

The peripheral circuit 30 may include a pass transistor 32, a row decoder 34, a page buffer 36, and a control logic circuit 38. The peripheral circuit 30 may further include one or more of: a data input and output circuit, an input and output interface, a column logic, a voltage generator, a pre-decoder, a temperature sensor, a command decoder, an address decoder, an amplification circuit, etc.

The memory cell array 20 may be connected to the pass transistor circuit 32 through a word line WL, a string selection line SSL, and a ground selection line GSL and may be connected to the page buffer 34 through a bit line BL. The memory cell array 20 may include a plurality of memory cells, which, for example, may include flash memory cells. Hereinafter, implementations are described in detail based on examples in which a plurality of memory cells are NAND flash memory cells. However, the disclosure is not limited thereto. According to some implementations, the plurality of memory cells may include resistive memory cells, such as resistive random-access memory (ReRAM), phase change random-access memory (PRAM), and magnetic random-access memory (MRAM).

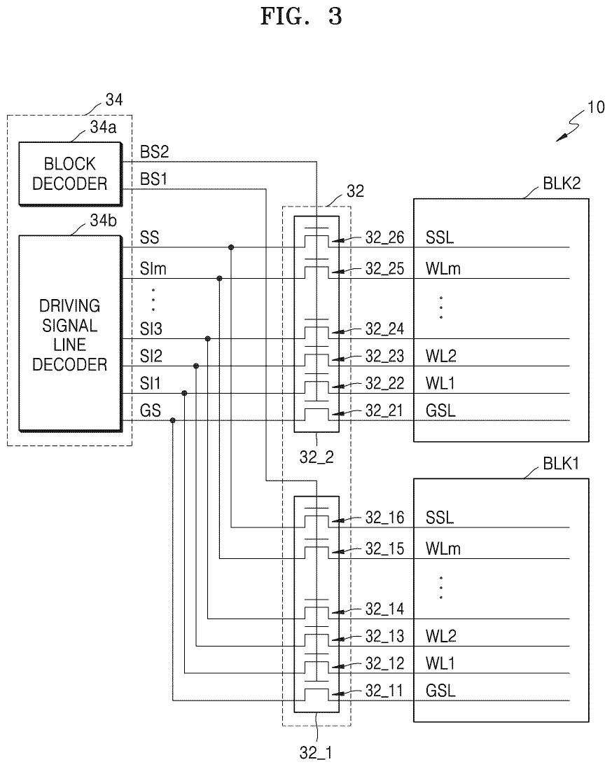

According to some implementations, the memory cell array 20 may include a three-dimensional (3D) memory cell array. The 3D memory cell array may include a plurality of NAND strings, each of which may include memory cells respectively connected to word lines vertically stacked on a substrate. With respect to this aspect, descriptions are to be given in detail with reference to FIG. 3.

The control logic circuit 38 may generate, based on a command CMD, an address ADDR, and a control signal CTRL, various control signals for programming data on the memory cell array 20, reading data from the memory cell array 20, or erasing data stored on the memory cell array 20. For example, the control logic circuit 38 may output a row address X-ADDR and a column address Y-ADDR. By doing so, the control logic circuit 38 may generally control various operations in the semiconductor device 10.

In response to the row address X-ADDR, the row decoder 34 may output, to block selection signal lines BS, a block selection signal for selecting one of a plurality of memory blocks. Also, in response to the row address X-ADDR, the row decoder 34 may output, to word line driving signal lines SI, a word line driving signal for selecting one of word lines WL of the selected memory block, may output, to string selection line driving signal lines SS, a string selection line driving signal for selecting one of string selection lines SSL of the selected memory block, and may output, to ground selection line driving signal lines GS, a ground selection line driving signal for selecting one of ground selection lines GSL of the selected memory block. The page buffer 36 may select one or more of bit lines BL, in response to the column address Y-ADDR. In detail, the page buffer 36 may operate as a write driver or a sense amplifier according to an operation mode.

The pass transistor 32 may be connected to the row decoder 34 through the block selection signal lines BS, the string selection line driving signal lines SS, the word line driving signal lines SI, and the ground selection line driving signal lines GS. The string selection line driving signal lines SS, the word line driving signal lines SI, and the ground selection line driving signal lines GS may be referred to as “driving signal lines.” The pass transistor circuit 32 may include a plurality of pass transistors (for example, 32_11 to 32_16 and 32_21 to 32_26 of FIG. 3), the plurality of pass transistors may be controlled by the block selection signals received through the plurality of selection signal lines BS and may provide the string selection line driving signals, the word line driving signals, and the ground selection line driving signals to the string selection lines SSL, the word lines WL, and the ground selection lines GSL, respectively.

According to implementations, the plurality of pass transistors may have a structure in which adjacent pass transistors may share a common gate, and the plurality of pass transistors may have a symmetrical arrangement or symmetrical structure in which the pass transistors sharing the common gate may be configured to provide an operating voltage to the same memory block According to implementations, the plurality of pass transistors may further include a field plate electrode connected to a gate structure. The pass transistors may be configured to apply an additional electric field to an active region, and thus, the pass transistors may have increased operating currents and/or increased breakdown voltages.

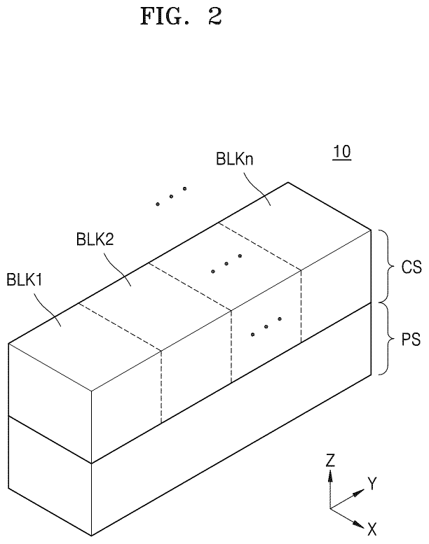

FIG. 2 is a schematic perspective view of the semiconductor device 10 according to implementations.

Referring to FIG. 2, the semiconductor device 10 may include a cell array structure CS and a peripheral circuit structure PS overlapping each other in a vertical direction.

The cell array structure CS may include the memory cell array 20 described with reference to FIG. 1. The peripheral circuit structure PS may include the peripheral circuit 30 described with reference to FIG. 1.

The cell array structure CS may include a plurality of memory blocks, namely, first to n^{th} memory blocks BLK1, BLK2, . . . , and BLKn. Each of the plurality of memory cell blocks, namely, the first to n^{th} memory blocks BLK1, BLK2, . . . , and BLKn, may include three-dimensionally arranged memory cells.

FIG. 3 is a schematic view of the pass transistor circuit 32 according to implementations.

Referring to FIG. 3, the semiconductor device 10 may include the pass transistor circuit 32, and the pass transistor circuit 32 may include a plurality of pass transistor circuits respectively corresponding to a plurality of memory blocks. The first and second memory blocks BLK1 and BLK2 may be arranged to be adjacent to each other, and each of the first and second memory blocks BLK1 and BLK2 may include a ground selection line GSL, a plurality of word lines WL1 to WLm, and a string selection line SSL, wherein m is a positive integer.

The row decoder 34 may include a block decoder 34a and a driving signal line decoder 34b. The pass transistor circuit 32 may include a pass transistor circuit 32_1 corresponding to the first memory block BLK1 and a pass transistor circuit 32_2 corresponding to the second memory block BLK2. The pass transistor circuit 32_1 may include a plurality of pass transistors 32_11 to 32_16, and the pass transistor circuit 32_2 may include a plurality of pass transistors 32_21 to 32_26.

The block decoder 34a may be connected to the pass transistor circuit 32_1 through a first block selection signal line BS1 and may be connected to the pass transistor circuit 32_2 through a second block selection signal line BL2. The first block selection signal line BS1 may be connected to gates of the plurality of pass transistors 32_11 to 32_16. For example, when a first block selection signal provided through the first block selection signal line BS1 is activated, the plurality of pass transistors 32_11 to 32_16 may be turned on, and thus, the first memory block BLK1 may be selected. Also, the second block selection signal line BS2 may be connected to gates of the plurality of pass transistors 32_21 to 32_26. For example, when a second block selection signal provided through the second block selection signal line BS2 is activated, the plurality of pass transistors 32_21 to 32_26 may be turned on, and thus, the second memory block BLK2 may be selected.

The driving signal line decoder 34b may be connected to the pass transistor circuits 32_1 and 32_2 through a string selection line driving signal line SS, word line driving signal lines SI1 to SIm, and a ground selection line driving signal line GS. In detail, each of the string selection line driving signal line SS, the word line driving signal lines SI1 to SIm, and the ground selection line driving signal line GS may be connected to sources of the plurality of pass transistors 32_11 to 32_16 and 32_21 to 32_26.

The pass transistor circuit 32_1 may be connected to the first memory block BLK1 through the ground selection line GSL, the plurality of word lines WL1 to WLm, and the string selection line SSL. The pass transistor 32_11 may be connected between the ground selection line driving signal line GS and the ground selection line GSL. The pass transistors 32_12 to 32_15 may be connected between the word line driving signal lines SI1 to SIm and the plurality of word lines WL1 to WLm, respectively. The pass transistor 32_16 may be connected between the string selection line driving signal line SS and the string selection line SSL. For example, when the first block selection signal is activated, the pass transistors 32_11 to 32_16 may provide driving signals respectively provided through the ground selection line driving signal line GS, the word line driving signal lines SI1 to SIm, and the string selection line driving signal line SS, to the ground selection line GSL, the plurality of word lines WL1 to WLm, and the string selection line SSL, respectively. The descriptions with respect to the pass transistor circuit 32_1 may be applied to the pass transistor circuit 32_2, and thus, the same descriptions are excluded.

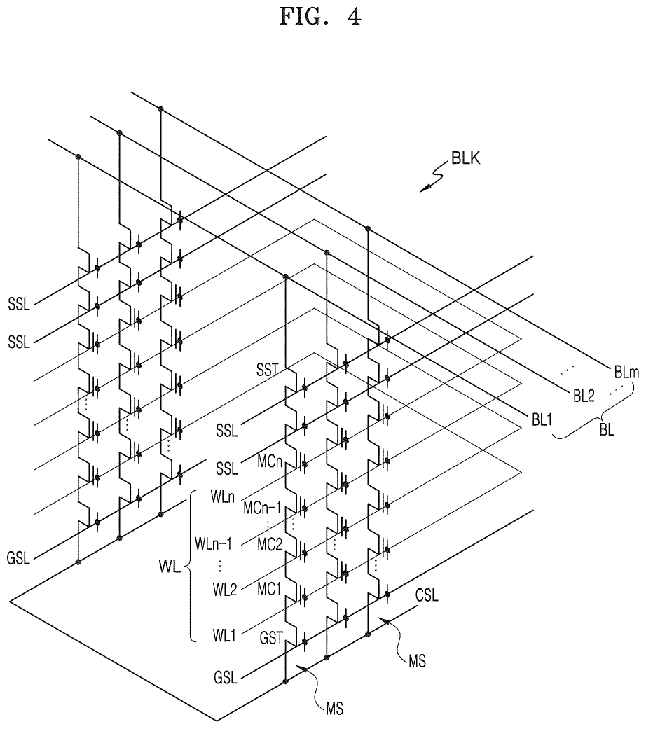

FIG. 4 is a circuit diagram of a memory block BLK according to implementations.

Referring to FIG. 4, the memory block BLK may include a plurality of memory cell strings MS arranged in a vertical direction. The memory block BLK may include a plurality of bit lines BL (e.g., BL1, BL2, . . . , and BLm), a plurality of word lines WL (e.g., namely, first to n^{th} word lines WL1, WL2, . . . , WLn-1, and WLn), at least one string selection line SSL, at least one ground selection line GSL, and a common source line CSL. The plurality of memory cell strings MS may be formed between the plurality of bit lines BL (e.g., BL1, BL2, . . . , and BLm) and the common source line CSL. FIG. 4 illustrates an example in which each of the plurality of memory cell strings MS includes two string selection lines SSL. However, the disclosure is not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, and MCn. A drain region of the string selection transistor SST may be connected to the bit lines BL (e.g., BL1, BL2, . . . , and BLm), and a source region of the ground selection transistor GST may be connected to the common source line CSL. The common source line CSL may be a region to which source regions of a plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, . . . , MCn-1, and MCn may be connected to the plurality of word lines WL (e.g., the first to n^{th} word lines WL1, WL2, . . . , WLn-1, and WLn), respectively.

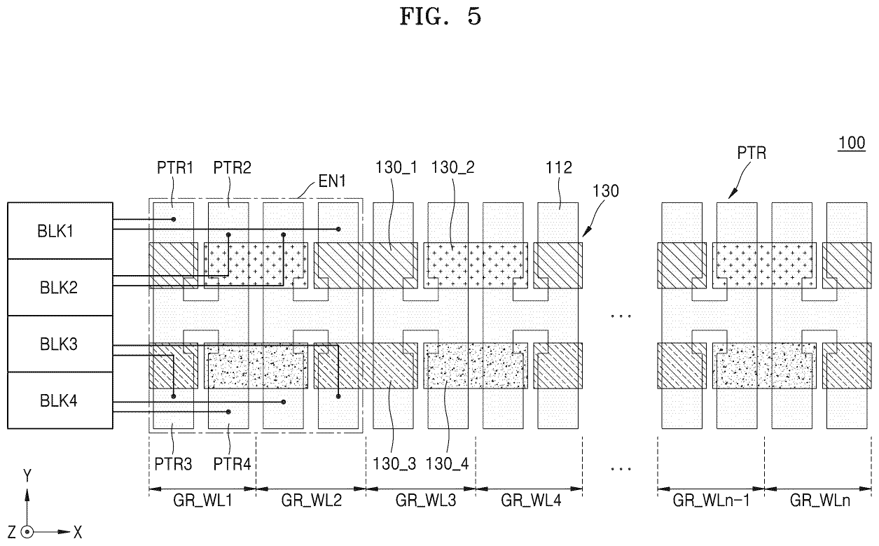

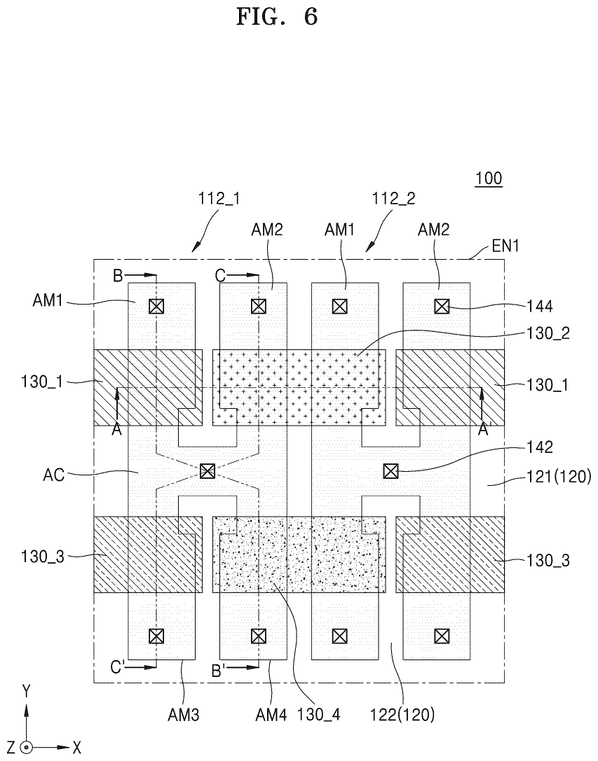

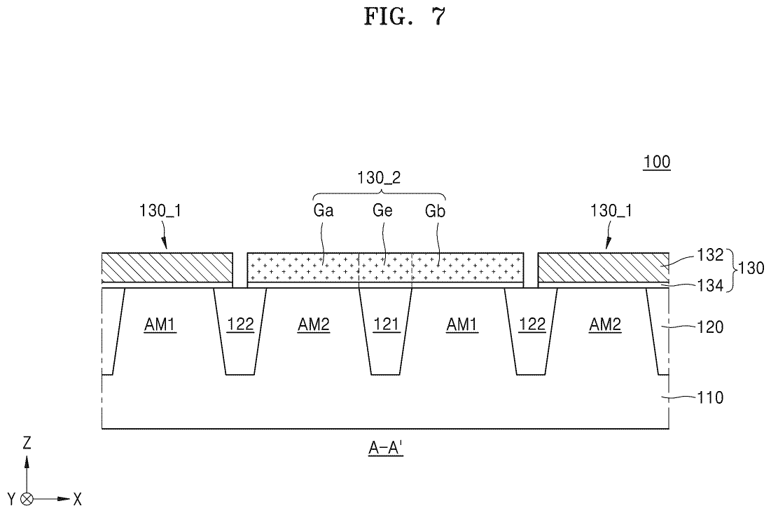

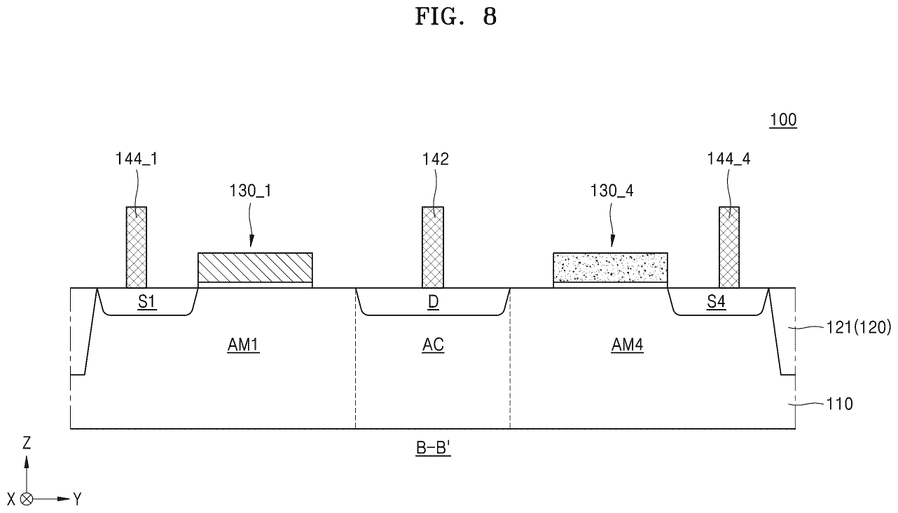

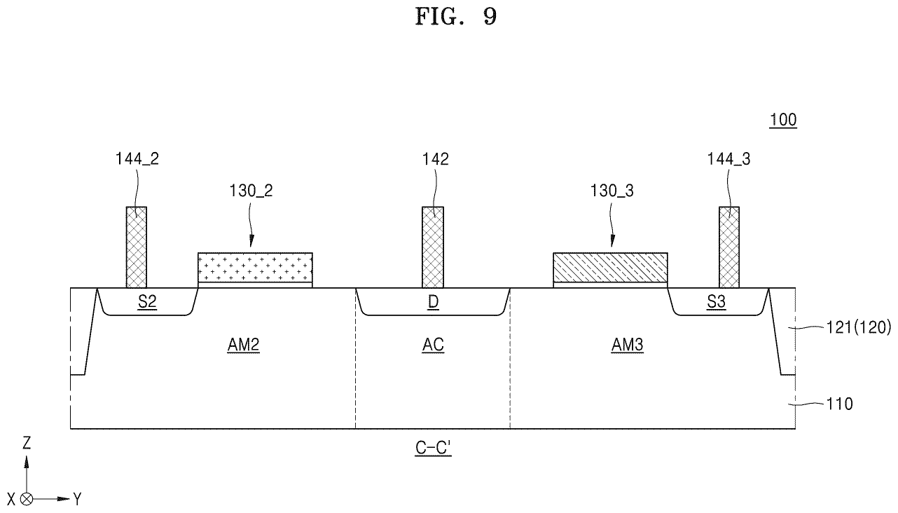

FIG. 5 is a layout diagram of a pass transistor included in a semiconductor device 100 according to implementations. FIG. 6 is an enlarged layout diagram of region EN1 of FIG. 5. FIG. 7 is a cross-sectional view of the semiconductor device 100 taken along line A-A′ of FIG. 6. FIG. 8 is a cross-sectional view of the semiconductor device 100 taken along line B-B′ of FIG. 6. FIG. 9 is a cross-sectional view of the semiconductor device 100 taken along line C-C′ of FIG. 6.

Referring to FIGS. 5 to 9, the semiconductor device 100 may include a plurality of active regions 112 defined on a substrate 110 and a plurality of gate structures 130 arranged on the plurality of active regions 112. The plurality of active regions 112 may be defined in the substrate 110 by a device isolation layer 120, and the gate structures 130 may be arranged on the active regions 112. The active region 112 and the gate structure 130 arranged on the active region 112 may form a pass transistor PTR. The semiconductor device 100 may be arranged in the peripheral circuit structure PS described with reference to FIG. 2.

According to implementations, as illustrated in FIG. 5, each of the plurality of active regions 112 may have an H-shape in a plan view and may be arranged to be apart from each other in a first horizontal direction X. Each of the active regions 112 may be included in each of pass transistor groups, namely, first to n^{th} pass transistor groups GR_WL1, GR_WL2, GR_WL3, GR_WL4, . . . , GR_WLn-1, and GR_WLn. According to implementations, each active region 112 may be shared by four pass transistors. According to implementations, each of the pass transistor groups, namely, the first to n^{th} pass transistor groups GR_WL1, GR_WL2, GR_WL3, GR_WL4, . . . , GR_WLn-1, and GR_WLn, may include a first pass transistor PTR1, a second pass transistor PTR2, a third pass transistor PTR3, and a fourth pass transistor PTR4 sharing one active region 112.

According to implementations, each of the pass transistor groups, namely, the first to n^{th} pass transistor groups GR_WL1, GR_WL2, GR_WL3, GR_WL4, . . . , GR_WLn-1, and GR_WLn, may be configured to transmit an operating voltage to the same word line included in each of four memory blocks. For example, the first pass transistor group GR_WL1 may be configured to transmit an operating voltage to first word lines included in the four memory blocks, and the second pass transistor group GR_WL2 may be configured to transmit an operating voltage to second word lines included in the four memory blocks.

According to implementations, in the first pass transistor group GR_WL1, the first pass transistor PTR1 may be configured to transmit the operating voltage to the first word line included in the first memory block BLK1, the second pass transistor PTR2 may be configured to transmit the operating voltage to the first word line included in the second memory block BLK2, the third pass transistor PTR3 may be configured to transmit the operating voltage to the first word line included in the third memory block BLK3, and the fourth pass transistor PTR4 may be configured to transmit the operating voltage to the first word line included in the fourth memory block BLK4.

According to implementations, two adjacent pass transistor groups may have a symmetrical structure with each other. For example, the first pass transistor group GR_WL1 and the second pass transistor group TR2_BL2 may have a symmetrical structure with each other. In this specification, that the first pass transistor group GR_WL1 and the second pass transistor group TR2_BL2 “have a symmetrical structure with each other” or “have a symmetrical arrangement with each other” may denote that the second pass transistor PTR2 in the first pass transistor group GR_WL1 and the first pass transistor PTR1 in the second pass transistor group GR_WL2 may be electrically connected to the same memory block, and the fourth pass transistor PTR4 in the first pass transistor group GR_WL1 and the third pass transistor PTR3 in the second pass transistor group GR_WL2 may be electrically connected to the same memory block.

According to implementations, in the second pass transistor group GR_WL2, the first pass transistor PTR1 may be configured to transmit the operating voltage to the second word line included in the second memory block BLK2, the second pass transistor PTR2 may be configured to transmit the operating voltage to the second word line included in the first memory block BLK1, the third pass transistor PTR3 may be configured to transmit the operating voltage to the second word line included in the fourth memory block BLK4, and the fourth pass transistor PTR4 may be configured to transmit the operating voltage to the second word line included in the third memory block BLK3.

According to implementations, each of the plurality of active regions 112 may include a central region AC and first to fourth main active regions AM1, AM2, AM3, and AM4. Each of the plurality of active regions 112 may have a H-shaped planar shape and may be arranged to be apart from each other in a direction (for example, a first horizontal direction X).

According to implementations, in a plan view, the central region AC may be arranged at the center of each active region 112. The first to fourth main active regions AM1 to AM4 may be connected to the central region AC.

According to implementations, a drain region D may be located above the central region AC. The drain region D may doped with first impurities. A drain contact 142 may be arranged on the drain region D. The drain contact 142 may receive an operating voltage from a voltage generation circuit included in the peripheral circuit 30 (see FIG. 1) and may transmit the operating voltage to the word line WL (see FIG. 1), the string selection line SSL (See FIG. 1), and the ground selection line GSL of a selected memory block. The operating voltage may be, for example, a program voltage. The program voltage may be a relatively high voltage, and, for example, may be in the range of 10 V to 30 V.

According to implementations, as illustrated in FIG. 6, the first to fourth main active regions AM1 to AM4 may be arranged to extend in a second horizontal direction Y from the central region AC. According to implementations, the first main active region AM1 and the second main active region AM2 may be arranged to be apart from each other in the first horizontal direction X. The third main active region AM3 and the fourth main active region AM4 may be arranged to be apart from each other in the first horizontal direction X. The central region AC may be arranged between the first main active region AM1 and the third main active region AM3 in the second horizontal direction Y, and the central region AC may be arranged between the second main active region AM2 and the fourth main active region AM4 in the second horizontal direction Y.

According to implementations, the substrate 110 may include a semiconductor substrate. For example, the substrate 110 may include a semiconductor material, for example, a group IV-based semiconductor, a groups III-V-based compound semiconductor, or a groups II-IV-based oxide semiconductor. For example, the group IV-based semiconductor may include Si, Ge, or Si—Ge. The substrate 110 may be provided as a bulk wafer or an epitaxial layer. According to another implementation, the substrate 110 may include a silicon-on-insulator (SOI) substrate or a germanium-on-insulator (GeOI) substrate.

According to implementations, the device isolation layer 120 may include, in a plan view, a first portion 121 arranged at an edge of each active region 112 and a second portion 122 extending from the first portion 121 toward an inner side of each active region 112.

According to implementations, the first portion 121 may include a portion of the device isolation layer 120 arranged between two adjacent active regions 112. According to implementations, the second portion 122 may include a portion of the device isolation layer 120 arranged between the first main active region AM1 and the second main active region AM2 and a portion of the device isolation layer 120 arranged between the third main active region AM3 and the fourth main active region AM4.

According to some implementations, the first main active region AM1 and the second main active region AM2 may be axially symmetrical with each other with respect to a virtual central line extending in a second horizontal direction Y across a central portion of the central region AC, and the third main active region AM3 and the fourth main active region AM4 may be axially symmetrical with each other with respect to the virtual central line.

A first source region S1, a second source region S2, a third source region S3, and a fourth source region S4 may be located at upper portions of the first main active region AM1, the second main active region AM2, the third main active region AM3, and the fourth main active region AM4, respectively. In detail, the first source region S1 may be located at the upper portion of the first main active region AM1, the second source region S2 may be located at the upper portion of the second main active region AM2, the third source region S3 may be located at the upper portion of the third main active region AM3, and the fourth source region S4 may be located at the upper portion of the fourth main active region AM4. The first to fourth main active regions AM1 to AM4 may be doped with second impurities. The second impurities may include, for example, n-type impurities, such as P.

A source contact 144 may be arranged on each of the first to fourth source regions S1 to S4. The source contact 144 may include a first source contact 144_1, a second source contact 144_2, a third source contact 144_3, and a fourth source contact 144_4, which may be connected to the first to fourth source regions S1 to S4, respectively. The first to fourth source contacts 144_1 to 144_4 may receive the operating voltage from the drain contact 142 and transmit the operating voltage to the word line WL (see FIG. 1), the string selection line SSL (see FIG. 1), and the ground selection line GSL of a selected memory block. For example, when a memory block (for example, the first memory block BLK1) connected to the first source contact 144_1 is selected, the first source contact 144_1 may receive the operating voltage from the drain contact 142 and transmit the operating voltage to the word line of the first memory block BLK1.

According to implementations, the gate structure 130 may be arranged to extend in the first horizontal direction X across portions of the two adjacent active regions 112. The gate structure 130 may include a first gate structure 130_1, a second gate structure 130_2, a third gate structure 130_3, and a fourth gate structure 130_4. The first to fourth gate structures 130_1 to 130_4 may be arranged on the substrate 110 to be apart from each other.

FIG. 6 illustrates that two active regions 112 are sequentially arranged in the first horizontal direction X. Here, the plurality of active regions 112 may include a first active region 112_1 and a second active region 112_2 arranged to be apart from each other in the first horizontal direction X. For example, the first active region 112_1 may be configured to transmit an operating voltage to the first word line WL1 (see FIG. 3) included in each of the first to fourth memory blocks BLK1 to BLK4. The second active region 112_2 may be configured to transmit an operating voltage to the second word line WL2 (see FIG. 3) included in each of the first to fourth memory blocks BLK1 to BLK4.

In detail, the first gate structure 130_1 may be arranged on the first main active region AM1 of the substrate 110, the second gate structure 130_2 may be arranged on the second main active region AM2 of the substrate 110, the third gate structure 130_3 may be arranged on the third main active region AM3 of the substrate 110, and the fourth gate structure 130_4 may be arranged on the fourth main active region AM4 of the substrate 110 to be apart from each other. The first to fourth gate structures 130_1 to 130_4 arranged on the first active region 112_1 may be arranged in a diagonal direction with respect to the drain contact 142 arranged on the central region AC of the first active region 112_1.

A first channel region, a second channel region, a third channel region, and a fourth channel region may be respectively arranged at upper portions of the first to fourth main active regions AM1 to AM4 respectively overlapping the first to fourth gate structures 130_1 to 130_4 in a vertical direction Z perpendicular to the first horizontal direction X and the second horizontal direction Y. For example, the first channel region may be located at the upper portion of the first main active region AM1 overlapping the first gate structure 130_1 in the vertical direction Z.

The first gate structure 130_1 may form the first pass transistor PTR1 together with the first source region S1 and the drain region D. The second gate structure 130_2 may form the second pass transistor PTR2 together with the second source region S2 and the drain region D. The third gate structure 130_3 may form the third pass transistor PTR3 together with the third source region S3 and the drain region D. The fourth gate structure 130_4 may form the fourth pass transistor PTR4 together with the fourth source region S4 and the drain region D. That is, as described above, the first to fourth pass transistors PTR1 to PTR4 may share one drain region D.

According to implementations, as described above, the gate structure 130 may be arranged to extend in the first horizontal direction X across the portions of the two adjacent active regions 112. According to implementations, the second gate structure 130_2 may be arranged on the second main active region AM2 of the first active region 112_1 and the first main active region AM1 of the second active region 112_2, and the fourth gate structure 130_4 may be arranged on the fourth main active region AM4 of the first active region 112_1 and the third main active region AM3 of the second active region 112_2.

According to implementations, as illustrated in FIG. 7, the second gate structure 130_2 may include a first electrode region Ga vertically overlapping the second main active region AM2 of the first active region 112_1, a second electrode region Gb vertically overlapping the first main active region AM1 of the second active region 112_2, and an electrode connection portion Ge arranged between the second main active region AM2 of the first active region 112_1 and the first main active region AM1 of the second active region 112_2 and vertically overlapping the first portion 121 of the device isolation layer 120. FIG. 7 illustrates that the second gate structure 130_2 may include the first electrode region Ga, the second electrode region Gb, and the electrode connection portion Ge. However, all of the first gate structure 130_1, the third gate structure 130_3, and the fourth gate structure 130_4 may be arranged across portions of two adjacent active regions 112, and thus, may have substantially the same structure (that is, a structure including the first electrode region Ga, the second electrode region Gb, and the electrode connection portion Ge) as the second gate structure 130_2.

According to implementations, as described above, one active region 112 may be electrically connected to the same memory block as the other active region 112 adjacent to the one active region 112. One pass transistor PTR including the one active region 112 may be electrically connected to the same memory block as another pass transistor PTR including the other active region 112 adjacent to the one active region 112.

According to implementations, the second main active region AM2 of the first active region 112_1 may be configured to apply an operating voltage to the first word line WL1 included in the second memory block BLK2, and the first main active region AM1 of the second active region 112_2 may be configured to apply an operating voltage to the second word line WL2 included in the second memory block BLK2. Thus, the second main active region AM2 of the first active region 112_1 may be electrically connected to the first word line WL1 included in the second memory block BLK2, for example, through the second source contact 144_2. The first main active region AM1 of the second active region 112_2 may be electrically connected to the second word line WL2 included in the second memory block BLK2, for example, through the first source contact 144_1.

Likewise, the fourth main active region AM4 of the first active region 112_1 may be electrically connected to the first word line WL1 included in the fourth memory block BLK4, for example, through the fourth source contact 144_4. The third main active region AM3 of the second active region 112_2 may be electrically connected to the second word line WL2 included in the fourth memory block BLK4, for example, through the third source contact 144_3.

As described above, the second gate structure 130_2 may be arranged across the second main active region AM2 of the first active region 112_1 and the first main active region AM1 of the second active region 112_2 to vertically overlap the second main active region AM2 of the first active region 112_1 and the first main active region AM1 of the second active region 112_2. Thus, when a voltage is applied to the second gate structure 130_2, the electrode connection portion Ge of the second gate structure 130_2 may apply an electric field to the second main active region AM2 of the first active region 112_1 or the first main active region AM1 of the second active region 112_2. Thus, operating currents of the transistor included in the first main active region AM1 or the second main active region AM2 may be increased.

According to implementations, the first gate structure 130_1 arranged on the first main active region AM1 of the first active region 112_1 and the second gate structure 130_2 arranged on the second main active region AM2 of the first active region 112_1 may be arranged to be apart from each other in the first horizontal direction X. The first gate structure 130_1 and the second gate structure 130_2 may be arranged on the second portion 122 of the device isolation layer 120 to be apart from each other. Also, the third gate structure 130_3 arranged on the third main active region AM3 of the first active region 112_1 and the fourth gate structure 130_4 arranged on the fourth main active region AM4 of the first active region 112_1 may be arranged to be apart from each other in the first horizontal direction X. The third gate structure 130_3 and the fourth gate structure 130_4 may be arranged on the second portion 122 of the device isolation layer 120 to be apart from each other.

As illustrated in FIG. 7, the gate structure 130 may include a gate electrode 132 and a gate insulating layer 134. The gate electrode 132 may include metal such as tungsten, nickel, cobalt, and tantalum, metal silicide, such as tungsten silicide, nickel silicide, cobalt silicide, and tantalum silicide, doped polysilicon, or a combination thereof. The gate insulating layer 134 may include at least one of silicon oxide, silicon nitride, and a high-k dielectric material.

According to implementations, as illustrated in FIG. 7, an upper surface of the device isolation layer 120 may be coplanar with an upper surface of the substrate 110, and a bottom surface of the electrode connection portion Ge may be coplanar with a bottom surface of the first electrode region Ga and/or a bottom surface of the second electrode region Gb.

According to implementations, each of the plurality of active regions 112 may include the central region AC and the first to fourth main active regions AM1 to AM4 and may have an H-shaped horizontal cross-section, and thus, a structure in which one drain region D is shared by four pass transistors PTR may be formed. Accordingly, compared to a semiconductor device according to the related art, in which two pass transistors sharing one drain of an active region are formed, the area of each pass transistor may be reduced.

According to implementations, the gate structure 130 may function as a common gate arranged to cross portions of two adjacent active regions 112 and configured to apply an operating voltage to the same memory block. Also, the electrode connection portion Ge of the gate structure 130 may be configured to apply an additional electric field to the portions of the active region 112 arranged to be adjacent to each other. Thus, electrons may be allowed to rapidly accumulate in the active region 112 adjacent to the electrode connection portion Ge, to reduce the resistance of the active region 112.

It was identified through a simulation test that the semiconductor device 100 according to implementations might have further improved electrical performance compared to a semiconductor device according to a comparative implementation, in which a common gate was not included. For example, a turn-on current was measured by applying a high program voltage of about 30 V to the gate structure 130 of the pass transistor PTR and a turn-off current and a breakdown voltage were measured by applying an off voltage of 0 V to the gate structure 130 of the pass transistor PTR. The turn-on current when the program voltage was applied indicated a value increased by 15% or higher compared to a pass transistor according to the comparative implementation.

According to the implementations described above, the semiconductor device 100 may have reduced resistance in the active region 112 by having symmetrical arrangement of a common gate and a memory block, and thus, the semiconductor device 100 may have increased operating currents. Thus, even when the area of the pass transistor PTR is reduced, the semiconductor device 100 may have improved electrical performance.

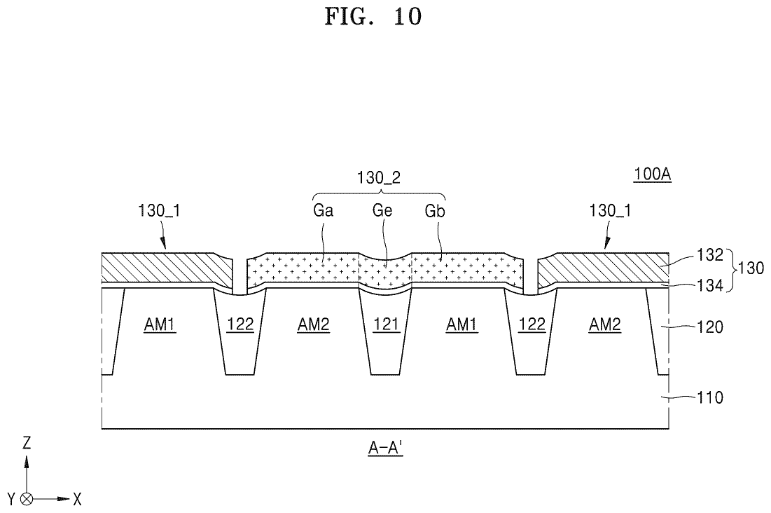

FIG. 10 is a cross-sectional view of a semiconductor device 100A according to implementations.

Referring to FIG. 10, an upper surface of the device isolation layer 120 may be recessed or dented in a direction toward a bottom side, for example, toward the substrate 110. According to implementations, the upper surface of the device isolation layer 120, that is, an upper surface of the first portion 121 and an upper surface of the second portion 122, may be vertically lower than an upper surface of the substrate 110. In a manufacturing method according to implementations, the upper surface of the device isolation layer 120 may be lowered by performing a recess process after the device isolation layer 120 is formed.

According to implementations, the electrode connection portion Ge of the gate structure 130 may be arranged on the upper surface of the first portion 121 of the device isolation layer 120, and the bottom surface of the electrode connection portion Ge may be arranged to be vertically lower than the bottom surface of the first electrode region Ga and/or the bottom surface of the second electrode region Gb.

According to implementations, a distance between the electrode connection portion Ge and the first main active region AM1 or a distance between the electrode connection portion Ge and the second main active region AM2 may be relatively decreased, and thus, operating currents of the semiconductor device 100A may be increased.

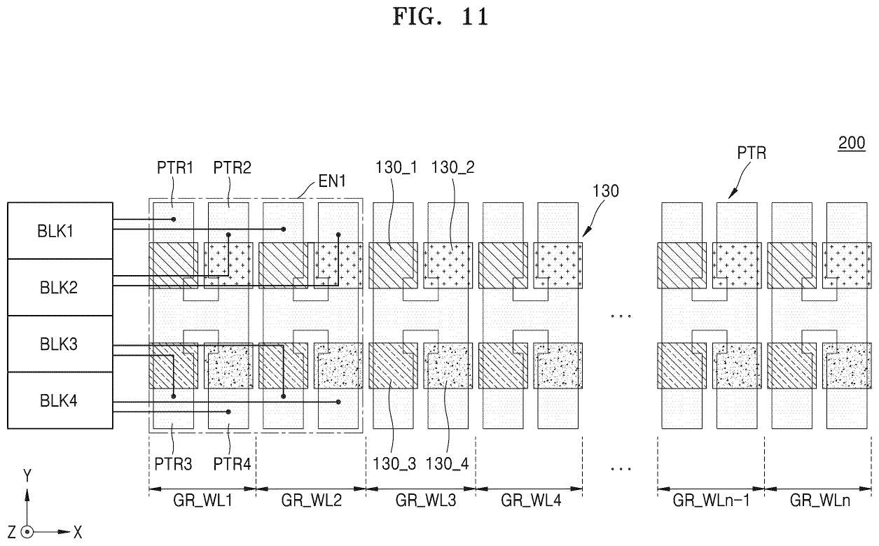

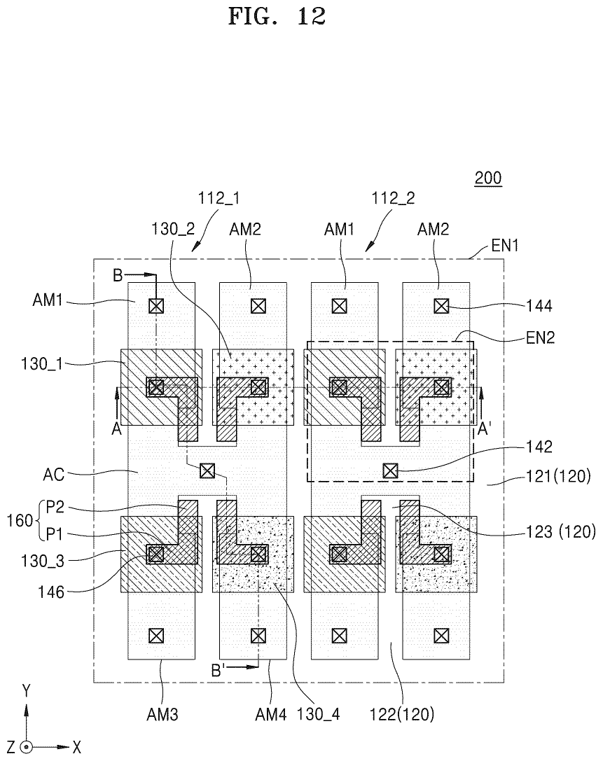

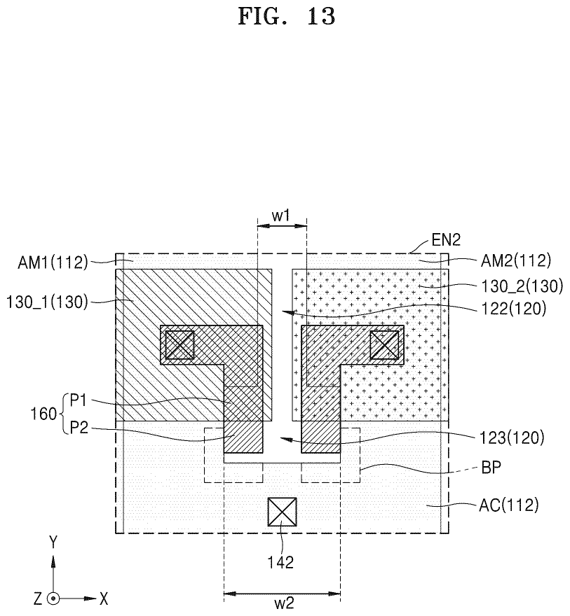

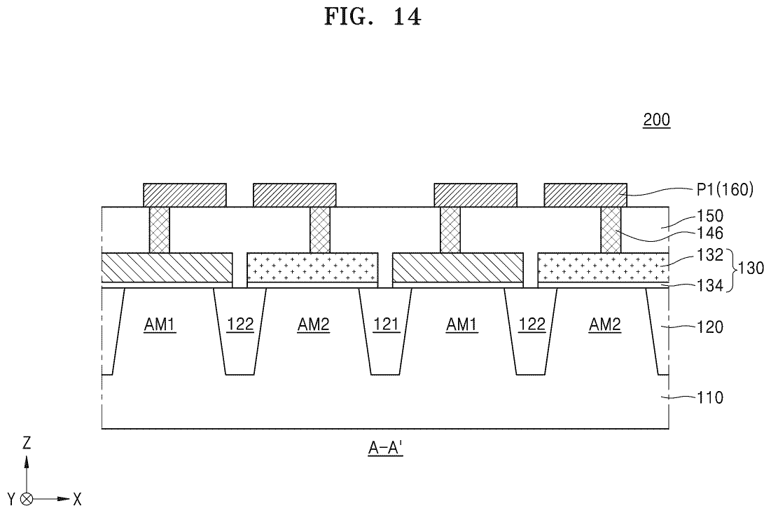

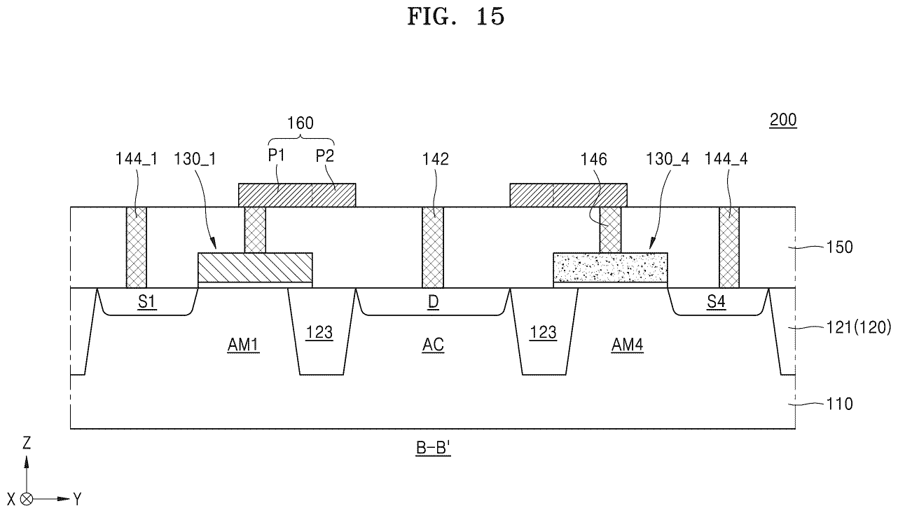

FIG. 11 is a layout diagram of a pass transistor included in a semiconductor device 200 according to implementations. FIG. 12 is an enlarged layout diagram of region EN1 of FIG. 11. FIG. 13 is an enlarged layout diagram of region EN2 of FIG. 12. FIG. 14 is a cross-sectional view of the semiconductor device 200 taken along line A-A′ of FIG. 12. FIG. 15 is a cross-sectional view of the semiconductor device 200 taken along line B-B′ of FIG. 12.

Referring to FIGS. 11 to 15, the semiconductor device 200 may include the plurality of active regions 112 defined on the substrate 110 and the plurality of gate structures 130 arranged on the plurality of active regions 112. The plurality of active regions 112 may be defined on the substrate 110 by the device isolation layer 120, and the gate structures 130 may be arranged on the active regions 112. The active region 112 and the gate structure 130 arranged on the active region 112 may form the pass transistor PTR.

According to some implementations, two adjacent pass transistor groups may not have a symmetrical structure with each other according to some implementations illustrated in FIG. 11. For example, in the first pass transistor group GR_WL1, the first pass transistor PTR1 may be configured to transmit an operating voltage to the first word line included in the first memory block BLK1, and the second pass transistor PTR2 may be configured to transmit an operating voltage to the first word line included in the second memory block BLK2. Also, in the second pass transistor group GR_WL2, the first pass transistor PTR1 may be configured to transmit an operating voltage to the second word line included in the first memory block BLK1, and the second pass transistor PTR2 may be configured to transmit an operating voltage to the second word line included in the second memory block BLK2.

However, the disclosure is not limited thereto. According to other implementations, two adjacent pass transistor groups may have a symmetrical structure with each other.

According to implementations, four gate structures 130 may be arranged on each active region 112 to be apart from each other, the gate structure 130 arranged on one active region 112 may be arranged to be apart from the gate structure 130 arranged on the active region 112 adjacent to the one active region 112. For example, as illustrated in FIG. 12, the second gate structure 130_2 arranged on the second main active region AM2 of the first active region 112_1 may be arranged to be apart, in the first horizontal direction X, from the first gate structure 130_1 arranged on the first main active region AM1 of the second active region 112_2, and the second gate structure 130_2 arranged on the second main active region AM2 of the first active region 112_1 may be arranged to be apart, in the first horizontal direction X, from the first gate structure 130_1 arranged on the first main active region AM1 of the first active region 112_1.

As illustrated in FIG. 13, in a plan view, the device isolation layer 120 may include the first portion 121 arranged at an edge of each active region 112, the second portion 122 extending from the first portion 121 toward an inner portion of each active region 112, and a third portion 123 integrally connected to the second portion 122 and at least partially surrounded by the central region AC.

According to implementations, the second portion 122 may have a first width w1 in the first horizontal direction X, and the third portion 123 may have a second width w2 that is greater than the first width w1 in the first horizontal direction X. The second portion 122 and the third portion 123 may collectively have a hammer-shaped horizontal cross-section.

According to implementations, the third portion 123 of the device isolation layer 120 may be formed to have a greater width than the second portion 122, and thus, the active region 112 may have a bending portion BP in a plan view. The bending portion BP may indicate a portion in the central region AC of each active region 112, the portion being adjacent to a corner of the third portion 123 of the device isolation layer 120. In other words, the bending portion BP may indicate a portion of the central region AC that is adjacent to the third portion 123 of the device isolation layer 120 and has an L shape in a plan view.

As illustrated in FIG. 13, one bending portion BP arranged to be adjacent to the first gate structure 130_1 and arranged to be adjacent to a first corner (or a left corner in the drawing) of the third portion 123 of the device isolation layer 120 may have a symmetrical shape with another bending portion BP arranged to be adjacent to the second gate structure 130_2 and arranged to be adjacent to a second corner (or a right corner in the drawing) of the third portion 123 of the device isolation layer 120. For example, the one bending portion BP and the other bending portion BP may be axially symmetrical with each other with respect to a virtual central line extending in a second horizontal direction Y across a central portion of the central region AC.

According to implementations, an insulating layer 150 covering the gate structure 130 may be arranged on the substrate 110, and a gate contact 146 passing through the insulating layer 150 and connected to the gate structure 130 may be arranged on the substrate 110. The drain contact 142 passing through the insulating layer 150 and connected to the drain region D of the central region AC may further be arranged on the substrate 110. The source contact 144 passing through the insulating layer 150 and connected to the first to fourth source regions S1 to S4 of the first to fourth main active regions AM1 to AM4 may further be arranged on the substrate 110.

According to implementations, a field plate electrode 160 connected to the gate contact 146 may be arranged on the insulating layer 150. As illustrated in FIG. 13, the field plate electrode 160 may include a first conductive layer portion P1 arranged to vertically overlap the gate structure 130. The field plate electrode 160 may include a second conductive layer portion P2 arranged to vertically overlap the third portion 123 of the device isolation layer 120 and not to vertically overlap the gate structure 130. The second conductive layer portion P2 may be integrally connected to the first conductive layer portion P1.

According to implementations, the second conductive layer portion P2 of the field plate electrode 160 may be arranged not to overlap the first to fourth main active regions AM1 to AM4 and/or the central region AC. As illustrated in FIG. 13, the second conductive layer portion P2 of the field plate electrode 160 may be arranged on the third portion 123 of the device isolation layer 120.

According to implementations, it is illustrated that the field plate electrode 160 may have an L shape in a plan view. However, the planar shape of the field plate electrode 160 is not limited thereto.

According to implementations, the field plate electrode 160 may be electrically connected to the gate structure 130 by the gate contact 146, and when a voltage is applied to the gate structure 130, the same voltage may be applied to the field plate electrode 160. The field plate electrode 160 may be configured to apply an additional electric field to a portion of the active region 112, the portion being adjacent to the third portion 123 of the device isolation layer 120. Thus, electrons may rapidly accumulate in the portion of the active region 112, the portion being adjacent to the third portion 123 of the device isolation layer 120, for example, in the bending portion BP, and the resistance of the bending portion BP may be reduced. Also, the first conductive layer portion P1 of the field plate electrode 160 may be arranged to vertically overlap the gate structure 130, and thus, undesired coupling due to the field plate electrode 160 may be prevented and/or minimized.

It was identified through a simulation test that the semiconductor device 200 according to implementations might have further improved electrical performance compared to a semiconductor device according to a comparative implementation, in which a field plate electrode was not included. For example, a turn-on current was measured by applying a high program voltage of about 30 V to the gate structure 130 of the pass transistor PTR and a turn-off current and a breakdown voltage were measured by applying an off voltage of 0 V to the gate structure 130 of the pass transistor PTR. The turn-on current when the program voltage was applied indicated a value increased by about 15.6 % compared to a pass transistor according to the comparative implementation. The breakdown voltage when the off voltage was applied was increased by about 5.9 V compared to the pass transistor according to the comparative implementation, which corresponds to a 22 % increase in value compared to the pass transistor according to the comparative implementation.

According to the implementations described above, the semiconductor device 200 including the field plate electrode 160 may have reduced resistance in the bending portion BP and minimized undesired coupling, so as to have improved operating currents and improved breakdown voltage characteristics.

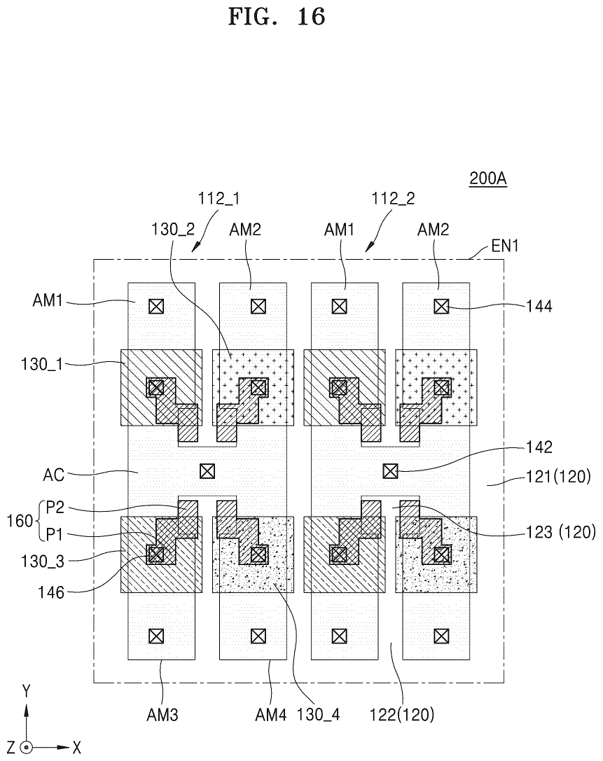

FIG. 16 is a layout diagram of a semiconductor device 200A according to implementations.

Referring to FIG. 16, the field plate electrode 160 may include the first conductive layer portion P1 overlapping the gate structure 130 and the second conductive layer portion P2 integrally connected to the first conductive layer portion P1 and vertically overlapping the third portion 123 of the device isolation layer 120. FIG. 16 illustrates that the first conductive layer portion P1 may have a planar shape having zigzag patterns. However, the disclosure is not limited thereto, and the first conductive layer portion P1 may have various planar shapes vertically overlapping the gate structure 130.

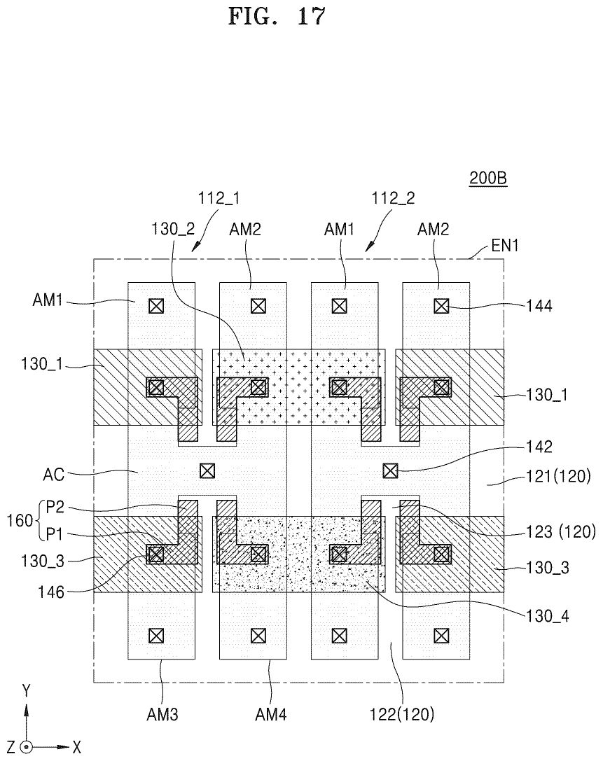

FIG. 17 is a layout diagram of a semiconductor device 200B according to implementations.

Referring to FIG. 17, the semiconductor device 200B may have layout characteristics of the pass transistor similar to those of the semiconductor device 100 described with reference to FIGS. 5 to 9. For example, the gate structure 130 may be arranged to overlap portions of two adjacent active regions 112. Also, the first active region 112_1 and the second active region 112_2 may be arranged to have a symmetrical structure (for example, one second gate structure 130_2 may be arranged on the second main active region AM2 of the first active region 112_1 and the first main active region AM1 of the second active region 112_2, and the second main active region AM2 of the first active region 112_1 and the first main active region AM1 of the second active region 112_2 may be configured to apply operating voltages to different word lines WL arranged in the same memory block BLK).

The semiconductor device 200B may further include the field plate electrode 160 electrically connected to the gate structure 130 and may have reduced resistance in the bending portion BP (see FIG. 13) and minimized undesired coupling, through the field plate electrode 160, so as to have improved operating currents and improved breakdown voltage characteristics.

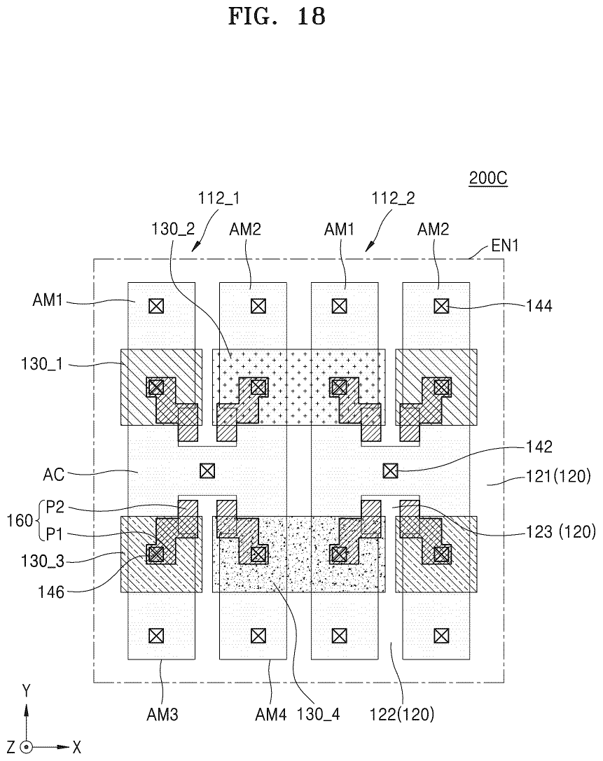

FIG. 18 is a layout diagram of a semiconductor device 200C according to implementations.

Referring to FIG. 18, the semiconductor device 200C may have the layout characteristics of the pass transistor, similar to those of the semiconductor device 100 described with reference to FIGS. 5 to 9. For example, the gate structure 130 may be arranged to overlap portions of two adjacent active regions 112. Also, the first active region 112_1 and the second active region 112_2 may be arranged to have a symmetrical structure. The first conductive layer portion P1 of the field plate electrode 160 may have a planar shape having zigzag patterns. However, the disclosure is not limited thereto, and the first conductive layer portion P1 may have various planar shapes vertically overlapping the gate structure 130.

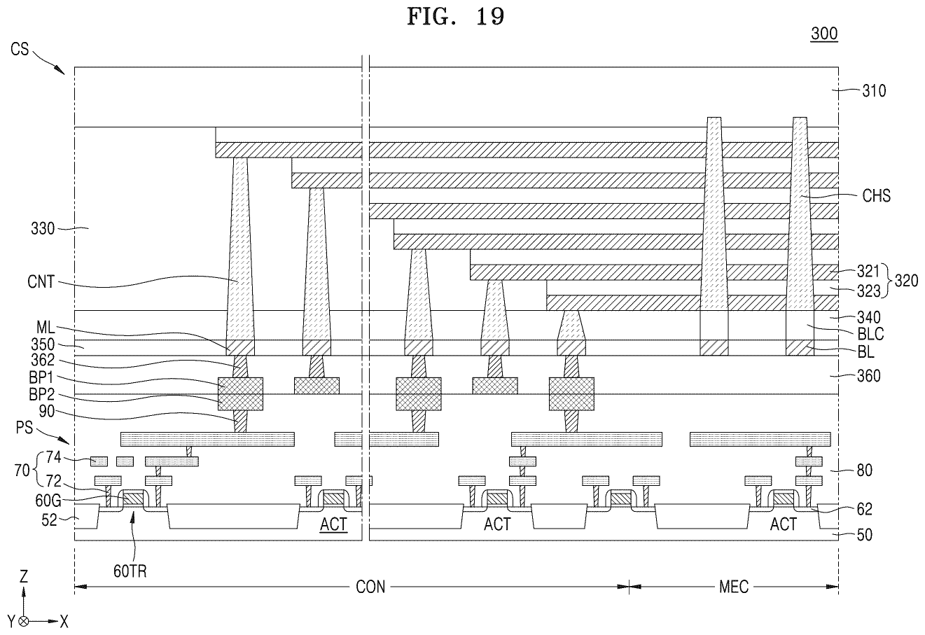

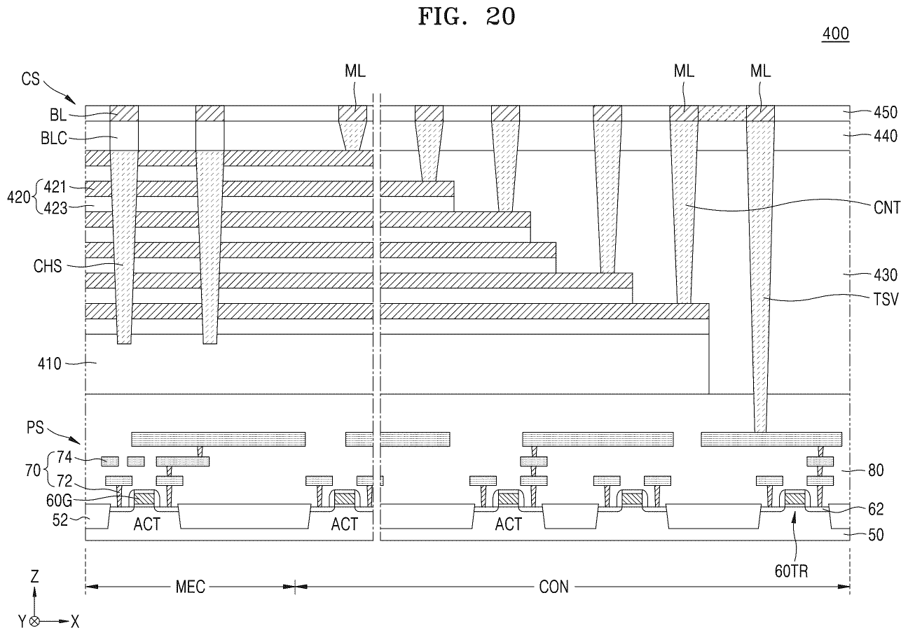

FIGS. 19 and 20 are respectively cross-sectional views of semiconductor devices 300 and 400 according to implementations.

Referring to FIG. 19, the semiconductor device 300 may include the cell array structure CS and the peripheral circuit structure PS overlapping each other in a vertical direction (a Z direction). According to some implementations, the cell array structure CS may be arranged to be vertically higher than the peripheral circuit structure PS. The cell array structure CS may include a memory cell region MEC and a connection region CON arranged at a side of the memory cell region MEC in a first horizontal direction (an X direction).

According to some implementations, the semiconductor device 300 may have a chip to chip (C2C) structure. The C2C structure may be acquired by forming the cell array structure CS on a first wafer and forming the peripheral circuit structure PS on a second wafer that is different from the first wafer, and then, connecting the cell array structure CS with the peripheral circuit structure PS through bonding. For example, bonding may indicate bonding of a first bonding pad BP1 of the cell array structure CS to a second bonding pad BP2 of the peripheral circuit structure PS for electrically connecting the first bonding pad BP1 to the second bonding pad BP2. According to implementations, when the first bonding pad BP1 and the second bonding pad BP2 include copper (Cu), the bonding may include Cu—Cu bonding. According to other implementations, each of the first bonding pad BP1 and the second bonding pad BP2 may include aluminum (Al) or tungsten (W).

The peripheral circuit structure PS may include a substrate 50, a peripheral circuit transistor 60TR arranged on the substrate 50, and a peripheral circuit line structure 70.

The substrate 50 may include a semiconductor substrate. For example, the substrate 50 may include Si, Ge, or SiGe. An active region ACT may be defined on the substrate 50 by a device isolation layer 54, and a plurality of peripheral circuit transistors 60TR may be formed on the active region AC. The plurality of peripheral circuit transistors 60TR may include a peripheral circuit gate 60G and source/drain regions 62 arranged on the substrate 50 at both sides of the peripheral circuit gate 60G. According to some implementations, the plurality of peripheral circuit transistors 60TR may include at least one of the structures of the pass transistor PTR included in the semiconductor devices 10, 100, 100A, 200, 200A, 200B, and 200C described above with reference to FIGS. 1 to 18.

A plurality of peripheral circuit line structures 70 may include a plurality of peripheral circuit contacts 72 and a plurality of peripheral circuit line layers 74. At some of the plurality of peripheral circuit line layers 74 may be configured to be electrically connected to the peripheral circuit transistor 60TR. The plurality of peripheral circuit contacts 72 may be configured to connect the plurality of peripheral circuit transistors 60TR with some selected from among the plurality of peripheral circuit line layers 74. The p lurality of peripheral circuit transistors 60TR and the plurality of peripheral circuit line structures 70 included in the peripheral circuit structure PS may be covered by an interlayer insulating layer 80. The interlayer insulating layer 80 may include a silicon oxide (SiO₂) layer, a silicon nitride (Si₃N₄) layer, a silicon oxynitride (SiON) layer, a silicon oxycarbonitride (SiOCN) layer, or a combination thereof.

The plurality of second bonding pads BP2 may be arranged on the interlayer insulating layer 80. The plurality of second bonding pads BP2 may be connected to the plurality of peripheral circuit line structures 70 through a second bonding via 90. According to some implementations, an upper surface of the second bonding pad BP2 may be arranged to be coplanar with an upper surface of the interlayer insulating layer 80. The second bonding pad BP2 may include a conductive material including copper (Cu), gold (Au), silver (Ag), aluminum (Al), tungsten (W), titanium (Ti), tantalum (Ta), or a combination thereof.

The cell array structure CS may include a gate stack 320 arranged on a substrate 310. The gate stack 320 may include a plurality of gate electrodes 321 and a plurality of insulating layers 323 alternately arranged in the vertical direction. The plurality of gate electrodes 321 may include, for example, tungsten, nickel, cobalt, tantalum, tungsten nitride, titanium nitride, tantalum nitride, or a combination thereof. The plurality of insulating layers 323 may include silicon oxide, silicon nitride, or silicon oxynitride. The plurality of gate electrodes 321 may correspond to a ground selection line GSL, a word line WL, and at least one string selection line SSL included in the memory cell string MS (see FIG. 4).

The gate stack 320 may have a stair shape on the connection region CON and may extend to have a decreased length in the first horizontal direction (the X direction) away from the substrate 310. For example, the gate stack 320 may extend on the connection region CON to have an increased length in the first horizontal direction (the X direction) away from the peripheral circuit structure PS. According to other implementations, rather than having a stair shape on the connection region CON, the gate stack 320 may extend to have the same length in the first horizontal direction (the X direction) away from the substrate 310.

The substrate 310 and the gate stack 320 may be covered by a cover insulating layer 330. The cover insulating layer 330 may include a silicon oxide layer, a silicon nitride layer, or a combination thereof.

A plurality of channel structures CHS may pass through the gate stack 320 and extend in a vertical direction on the memory cell region MEC. Each of the plurality of channel structures CHS may be arranged in a channel hole passing through the gate stack 320. Each of the plurality of channel structures CHS may include a gate insulating layer, a channel layer, a buried insulating layer, and a conductive plug. The gate insulating layer and the channel layer may be sequentially arranged on a side wall of the channel hole. The buried insulating layer filling the remaining space of the channel hole may be arranged on the channel layer. The conductive plug may be arranged to be in contact with the channel layer to block the entrance of the channel hole.

Lower surface portions of the plurality of channel structures CHS may be in contact with a plurality of bit line contacts BLC. The plurality of bit line contacts BLC may pass through a first insulating layer 340 and extend in the vertical direction (the Z direction), and may be insulated from each other by the first insulating layer 340. Lower surface portions of the plurality of bit line contacts BLC may be in contact with a plurality of bit lines BL. The plurality of bit lines BL may pass through a second insulating layer 350 and extend in the vertical direction (the Z direction), and may be insulated from each other by the second insulating layer 350. Each of the plurality of channel structures CHS may be connected to one of the plurality of bit lines BL corresponding thereto, through the bit line contact BLC.

A plurality of contact structures CNT may pass through the cover insulating layer 330 and the first insulating layer 340 and extend in the vertical direction (the Z direction) on the connection region CON. The plurality of contact structures CNT may electrically connect the plurality of gate electrodes 321 with a plurality of line layers ML. For example, upper surface portions of the plurality of contact structures CNT may be in contact with the plurality of gate electrodes 321, and lower surface portions of the plurality of contact structures CNT may be in contact with the plurality of line layers ML. The plurality of line layers ML may pass through the second insulating layer 350 and extend in the vertical direction (the Z direction), and may be insulated from each other by the second insulating layer 350. Lower surface portions of the plurality of line layers ML may be in contact with a plurality of first bonding vias 362. The plurality of first bonding vias 362 may pass through an interlayer insulating layer 360 and extend in the vertical direction (the Z direction), and may be insulated from each other by the interlayer insulating layer 360. A lower surface portion of the first bonding via 362 may be in contact with the first bonding pad BP1.

From among the plurality of peripheral circuit transistors 60TR, the peripheral circuit transistor 60TR corresponding to the pass transistor PTR included in the semiconductor devices 10, 100, 100A, 200, 200A, 200B, and 200C described with reference to FIGS. 1 to 18, may be electrically connected to the plurality of gate electrodes 321 through the plurality of contact structures CNT. For example, from among the plurality of peripheral circuit transistors 60TR, the drain region D (see FIG. 8) of the semiconductor devices 10, 100, 100A, 200, 200A, 200B, and 200C described above with reference to FIGS. 1 to 18, may be electrically connected to the plurality of gate electrodes 321 through the plurality of contact structures CNT and may transmit an operating voltage. According to some implementations, the drain region D of the pass transistor PTR and the contact structure CNT corresponding thereto may be electrically connected to each other through the peripheral circuit line structure 70, the second bonding via 90, the second bonding pad BP2, the first bonding pad BP1, the first bonding via 362, and the line layer ML.

Referring to FIG. 20, the semiconductor device 400 may include the cell array structure CS and the peripheral circuit structure PS. Components of the semiconductor device 400 of FIG. 20 may be respectively and substantially the same as components of the semiconductor device 300 described with reference to FIG. 19, and thus, hereinafter, different aspects are mainly described.

The peripheral circuit structure PS of the semiconductor device 400 may be substantially the same as or similar to the peripheral circuit structure PS of the semiconductor device 300 described with reference to FIG. 19.

The cell array structure CS may include a gate stack 420 and a cell substrate 410 arranged between the gate stack 420 and the peripheral circuit structure PS. According to some implementations, the cell substrate 410 may include a semiconductor material such as polysilicon.

The gate stack 420 may be arranged on the cell substrate 410. The gate stack 420 may include a plurality of gate electrodes 421 and a plurality of insulating layers 423 alternately arranged in the vertical direction. The gate stack 420 may have a stair shape on the connection region CON and may extend to have a decreased length in the first horizontal direction (the X direction) away from the peripheral circuit structure PS and the cell substrate 410. That is, the gate stack 420 may have a stair shape. The gate stack 420 may be covered by a cover insulating layer 430. According to other implementations, rather than having a stair shape on the connection region CON, the gate stack 420 may extend to have the same length in the first horizontal direction (the X direction) away from the cell substrate 410.

The plurality of channel structures CHS may pass through the gate stack 420 and extend in the vertical direction (the Z direction) on the memory cell region MEC. Components of the plurality of channel structures CHS may be substantially the same as or similar to the components of the plurality of channel structures CHS described with reference to FIG. 19.

Upper surface portions of the plurality of channel structures CHS may be in contact with the plurality of bit line contacts BLC. The plurality of bit line contacts BLC may pass through a first insulating layer 440 and extend in the vertical direction (the Z direction), and may be insulated from each other by the first insulating layer 440. Upper surface portions of the plurality of bit line contacts BLC may be in contact with the plurality of bit lines BL. The plurality of bit lines BL may pass through a second insulating layer 450 and extend in the vertical direction (the Z direction), and may be insulated from each other by the second insulating layer 450. Each of the plurality of channel structures CHS may be connected to one of the plurality of bit lines BL corresponding thereto, through the bit line contact BLC.

The plurality of contact structures CNT may pass through the cover insulating layer 430 and the first insulating layer 440 and extend in the vertical direction (the Z direction) on the connection region CON. Upper surface portions of the plurality of contact structures CNT may be in contact with the plurality of line layers ML. The plurality of line layers ML may pass through a second insulating layer 450 and extend in the vertical direction (the Z direction), and may be insulated from each other by the second insulating layer 450.

A through-electrode TSV may pass through the first insulating layer 440, the cover insulating layer 430, and the interlayer insulating layer 80 and extend in the vertical direction (the Z direction), and may be electrically connected between the line layer ML and the peripheral circuit line layer 74. The through-electrode TSV may be electrically connected to the plurality of gate electrodes 421 through the line layer ML and the contact structure CNT.

From among the plurality of peripheral circuit transistors 60TR, the peripheral circuit transistor 60TR corresponding to the pass transistor PTR included in the semiconductor devices 10, 100, 100A, 200, 200A, 200B, and 200C described with reference to FIGS. 1 to 18, may be electrically connected to the plurality of gate electrodes 321 through the through-electrode TSV, the line layer ML, and the contact structure CNT. For example, from among the plurality of peripheral circuit transistors 60TR, the drain region D (see FIG. 8) of the pass transistor PTR included in the semiconductor devices 10, 100, 100A, 200, 200A, 200B, and 200C described with reference to FIGS. 1 to 18, may be electrically connected to the plurality of gate electrodes 321 through the through-electrode TSV, the line layer M, and the contact structure CNT and may transmit an operating voltage. According to some implementations, the drain region D of the pass transistor PTR and the through-electrode TSV corresponding thereto may be electrically connected to each other through the peripheral circuit line structure 70.

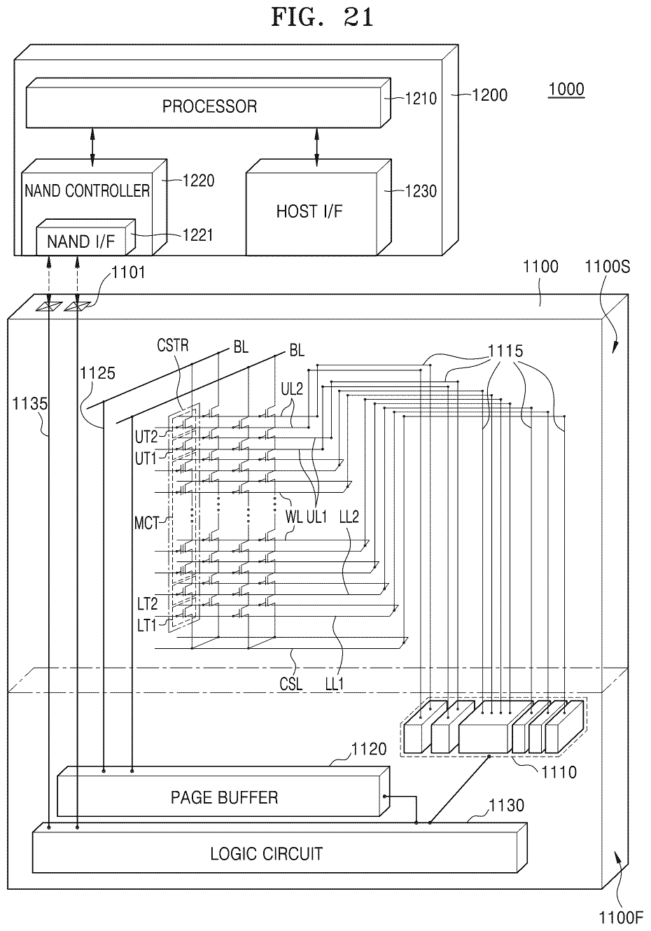

FIG. 21 is a schematic diagram of a data storage system 1000 including a semiconductor device according to implementations.

Referring to FIG. 21, the data storage system 1000 may include one or more semiconductor devices 1100 and a memory controller 1200 electrically connected to the one or more semiconductor devices 1100. The data storage system 1000 may include, for example, a solid state drive (SSD) device, a universal serial bus (USB), a computing system, a medical device, or a communication device including the one or more semiconductor devices 1100.

The semiconductor device 1100 may include a nonvolatile semiconductor device. For example, the semiconductor device 1100 may include a NAND flash semiconductor device including one of the semiconductor devices 10, 100, 100A, 200, 200A, 200B, 200C, 300, and 400 described with reference to FIGS. 1 to 20. The semiconductor device 1100 may include a first structure 1100F and a second structure 1100S on the first structure 1100F. The first structure 1100F may include a peripheral circuit structure including a row decoder 1110, a page buffer 1120, and a logic circuit 1130.

The second structure 1100S may include a memory cell structure including a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

Each of the plurality of memory cell strings CSTR in the second structure 1100S may include ground selection transistors LT1 and LT2 adjacent to the common source line CSL, string selection transistors UT1 and UT2 adjacent to the bit line BL, and a plurality of memory cell transistors MCT arranged between the ground selection transistors LT1 and LT2 and the string selection transistors UT1 and UT2. The number of ground selection transistors LT1 and LT2 and the number of string selection transistors UT1 and UT2 may be variously changed according to implementations.

According to implementations, the plurality of ground selection lines LL1 and LL2 may be respectively connected to gate electrodes of the ground selection transistors LT1 and LT2. The word line WL may be connected to a gate electrode of the memory cell transistor MCT. The plurality of string selection lines UL1 and UL2 may be connected to gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 through an input and output pad 1101 electrically connected to the logic circuit 1130. The input and output pad 1101 may be electrically connected to the logic circuit 1130.

The memory controller 1200 may include a processor 1210, a NAND controller 1220, and a host interface 1230. According to some implementations, the data storage system 1000 may include the one or more semiconductor devices 1100, and in this case, the memory controller 1200 may control the one or more semiconductor devices 1100.

The processor 1210 may control general operations of the data storage system 1000 including the memory controller 1200. The processor 1210 may operate according to certain firmware and may control the NAND controller 1220 to access the semiconductor device 1100. The NAND controller 1220 may include a NAND interface 1221 configured to process communication with the semiconductor device 1100. A control command for controlling the semiconductor device 1100, data to be written to the plurality of memory cell transistors MCT of the semiconductor device 1100, data to be read from the plurality of memory cell transistors MCT of the semiconductor device 1100, etc. may be transmitted through the NAND interface 1221. The host interface 1230 may provide a communication function between the data storage system 1000 and an external host. When a control command is received from the external host through the host interface 1230, the processor 1210 may control the semiconductor device 1100 in response to the control command.

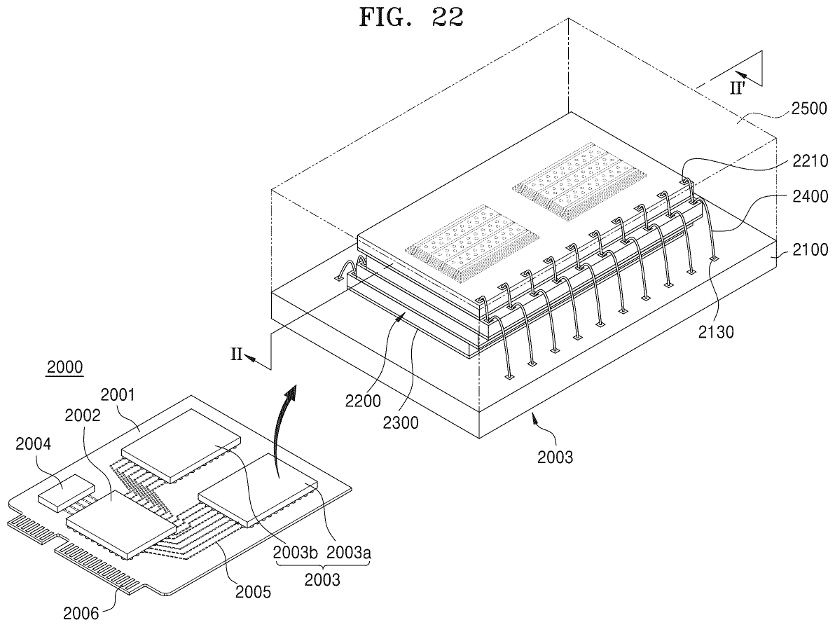

FIG. 22 is a schematic perspective view of a data storage system 2000 including a semiconductor device according to implementations.

Referring to FIG. 22, the data storage system 2000 according to some implementations may include a main substrate 2001, a memory controller 2002 mounted on the main substrate 2001, one or more semiconductor packages 2003, and dynamic random-access memory (DRAM) 2004. The semiconductor package 2003 and the DRAM 2004 may be connected to the memory controller 2002 by a plurality of line patterns 2005 formed on the main substrate 2001.

The main substrate 2001 may include a connector 2006 including a plurality of pins coupled to an external host. The number and the arrangement of the plurality of pins of the connector 2006 may vary according to a communication interface between the data storage system 2000 and the external host. According to implementations, the data storage system 2000 may communicate with the external host according to any one of the interfaces, such as a USB, peripheral component interconnect (PCI)-express, serial advanced technology attachment (SATA), M-Phy for a universal flash storage (UFS), etc. According to implementations, the data storage system 2000 may operate based on power supplied from the external host through the connector 2006. The data storage system 2000 may further include a power management integrated circuit (PMIC) configured to distribute the power supplied from the external host to the memory controller 2002 and the semiconductor package 2003.

The memory controller 2002 may write data to the semiconductor package 2003 or read data from the semiconductor package 2003 and may improve the operation speed of the data storage system 2000.

The DRAM 2004 may include a buffer memory configured to reduce a difference in speed between the external host and the semiconductor package 2003, which is a data storage space. The DRAM 2004 included in the data storage system 2000 may also operate as a type of cache memory and may provide a space for temporarily storing data in a control operation on the semiconductor package 2003. When the DRAM 2004 is included in the data storage system 2000, the memory controller 2002 may further include a DRAM controller configured to control the DRAM 2004, in addition to the NAND controller 1220 configured to control the semiconductor package 2003.

The semiconductor package 2003 may include first and second semiconductor packages 2003a and 2003b which are apart from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, a bonding layer 2300 arranged on a lower surface of each of the plurality of semiconductor chips 2200, a connection structure 2400 electrically connecting the plurality of semiconductor chips 2200 with the package substrate 2100, and a molding layer 2500 covering the plurality of semiconductor chips 2200 and the connection structure 2400 on the package substrate 2100.

The package substrate 2100 may include a printed circuit board including a plurality of package upper pads 2130. Each of the plurality of semiconductor chips 2200 may include an input and output pad 2210. The input and output pad 2210 may correspond to the input and output pad 1101 of FIG. 21. Each of the plurality of semiconductor chips 2200 may include at least one of the semiconductor devices 10, 100, 100A, 200, 200A, 200B, 200C, 300, and 400 described with reference to FIGS. 1 to 20.

According to implementations, the connection structure 2400 may include bonding wires electrically connecting the input and output pads 2210 with the package upper pads 2130. Thus, in the first and second semiconductor packages 2003a and 2003b, the plurality of semiconductor chips 2200 may be electrically connected to each other by a bonding wire method and may be electrically connected to the package upper pads 2130 of the package substrate 2100. According to some implementations, in the first and second semiconductor packages 2003a and 2003b, the plurality of semiconductor chips 2200 may be electrically connected to each other by a connection structure including a through silicon via (TSV), rather than by the connection structure 2400 using the bonding wire method.

According to implementations, the memory controller 2002 and the plurality of semiconductor chips 2200 may be included in one package. According to some implementations, the memory controller 2002 and the plurality of semiconductor chips 2200 may be mounted on an interposer substrate which is different from the main substrate 2001, and the memory controller 2002 and the plurality of semiconductor chips 2200 may be connected to each other through a line formed on the interposer substrate.

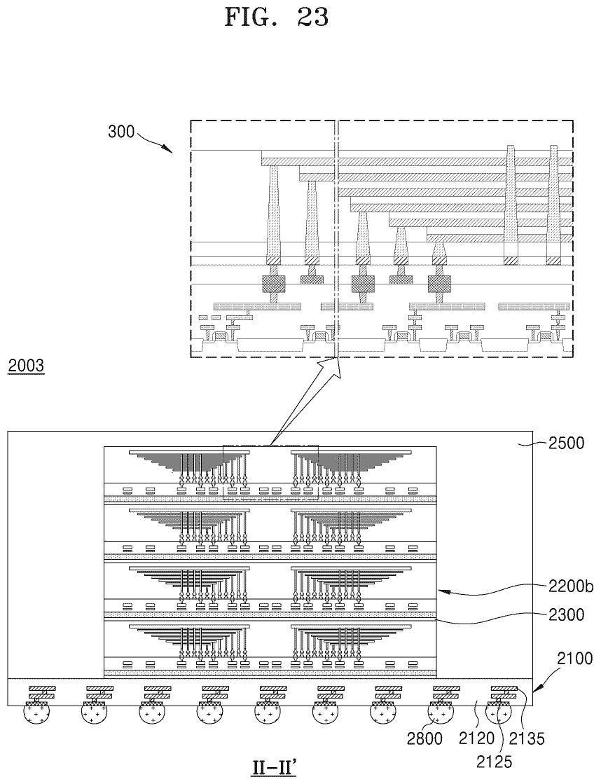

FIG. 23 is a schematic cross-sectional view of semiconductor packages 2003 according to implementations. FIG. 23 is a cross-sectional view of the semiconductor packages 2003 taken along line II-II′ of FIG. 22.

Referring to FIG. 23, in the semiconductor package 2003, the package substrate 2100 may include a printed circuit board. The package substrate 2100 may include a package substrate body portion 2120, a plurality of package upper pads 2130 (see FIG. 22) arranged on an upper surface of the package substrate body portion 2120, a plurality of lower pads 2125 arranged on or exposed through a lower surface of the package substrate body portion 2120, and a plurality of inner lines 2135 electrically connecting the plurality of package upper pads 2130 (see FIG. 22) with the plurality of lower pads 2125 in the package substrate body portion 2120. As illustrated in FIG. 23, the plurality of package upper pads 2130 may be electrically connected to the plurality of connection structures 2400. As illustrated in FIG. 23, the plurality of lower pads 2125 may be connected to the plurality of line patterns 2005 on the main substrate 2001 of the data storage system 2000 illustrated in FIG. 23 through a plurality of conductive bumps 2800. Each of the plurality of semiconductor chips 2200 may include at least one of the semiconductor devices 10, 100, 100A, 200, 200A, 200B, 200C, 300, and 400 described with reference to FIGS. 1 to 20.

According to the disclosure, a semiconductor device may include four pass transistors formed on an active region having an H shape, and because the area of each of the pass transistors may be reduced, the size of the semiconductor device including the pass transistors may be reduced. Operating currents may be increased due to a common gate between adjacent transistors, and the operating currents may be increased and breakdown voltages may be increased by a field plate electrode. Therefore, the electrical performance of the semiconductor device may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosure has been particularly shown and described with reference to implementations thereof, it will be understood that various changes in form and details may be made therein without departing from the spirit and scope of the following claims.

What is claimed is:

1. A semiconductor device comprising:
a substrate comprising a plurality of active regions defined by a device isolation layer, wherein each of the plurality of active regions comprises
a central region,
a first main active region and a second main active region extending from the central region and spaced apart from each other in a first horizontal direction, and
a third main active region and a fourth main active region extending from the central region, wherein the third and fourth main active regions are spaced apart from each other in the first horizontal direction, and are spaced apart from the first main active region and the second main active region in a second horizontal direction, and
wherein the plurality of active regions comprise a first active region and a second active region adjacent to each other in the first horizontal direction;
a first gate structure on the first main active region of the first active region; and
a second gate structure on the second main active region of the first active region and the first main active region of the second active region and spaced apart from the first gate structure.

2. The semiconductor device of claim 1, wherein the device isolation layer comprises a first portion between the first active region and the second active region and a second portion between the first main active region and the second main active region of each of the plurality of active regions, and
wherein the second gate structure comprises:
a first electrode region vertically overlapping the second main active region of the first active region,
a second electrode region vertically overlapping the first main active region of the second active region, and
an electrode connection portion between the first electrode region and the second electrode region.

3. The semiconductor device of claim 2, wherein the electrode connection portion vertically overlaps the first portion of the device isolation layer.

4. The semiconductor device of claim 2, wherein a bottom surface of the electrode connection portion is coplanar with a bottom surface of the first electrode region.

5. The semiconductor device of claim 2, wherein a bottom surface of the electrode connection portion is vertically lower than a bottom surface of the first electrode region.

6. The semiconductor device of claim 1, comprising:
a third gate structure on the third main active region of the first active region; and
a fourth gate structure on the fourth main active region of the first active region and the third main active region of the second active region and spaced apart from the third gate structure.

7. The semiconductor device of claim 6, wherein each of the plurality of active regions comprises a drain region in the central region of each of the plurality of active regions, and
wherein the drain region is surrounded by the first to fourth gate structures in a plan view.

8. The semiconductor device of claim 7, wherein each of the plurality of active regions comprises:
a first source region in the first main active region, wherein in the plan view, the first source region is at a side of the first gate structure;
a second source region in the second main active region, wherein in the plan view, the second source region is at a side of the second gate structure;
a third source region in the third main active region, wherein in the plan view, the third source region is at a side of the third gate structure; and
a fourth source region in the fourth main active region, wherein in the plan view, the fourth source region is at a side of the fourth gate structure.

9. The semiconductor device of claim 8, comprising:
a drain contact on the drain region;
a first source contact on the first source region;
a second source contact on the second source region;
a third source contact on the third source region; and
a fourth source contact on the fourth source region.

10. The semiconductor device of claim 1, wherein each of the plurality of active regions has an H shape in a plan view.

11. The semiconductor device of claim 6, wherein the plurality of active regions comprise a third active region spaced apart from the second active region in the first horizontal direction with the first active region therebetween,
wherein a portion of the first gate structure is on the second main active region of the third active region, and
wherein a portion of the third gate structure is on the fourth main active region of the third active region.

12. The semiconductor device of claim 1, comprising a cell array region on the substrate,
wherein the cell array region comprises:
a plurality of word lines spaced apart from each other in a vertical direction,
a plurality of channels passing through the plurality of word lines and extending in the vertical direction, and
a cell contact connected to one of the plurality of word lines, and
wherein the cell contact is electrically connected to one of the plurality of active regions.

13. The semiconductor device of claim 12, wherein the cell array region comprises a plurality of memory blocks,
wherein the first main active region of the first active region is electrically connected to a first word line included in a first memory block from among the plurality of memory blocks,
wherein the second main active region of the first active region is electrically connected to a first word line included in a second memory block from among the plurality of memory blocks, and
wherein the first main active region of the second active region is electrically connected to a second word line included in the second memory block.

14. A semiconductor device comprising:
a substrate comprising a plurality of active regions defined by a device isolation layer, wherein each of the plurality of active regions comprises
a central region,
a first main active region and a second main active region extending from the central region and spaced apart from each other in a first horizontal direction, and
a third main active region and a fourth main active region extending from the central region and spaced apart from the first main active region and the second main active region in a second horizontal direction; and
a plurality of gate structures overlapping portions of two adjacent active regions from among the plurality of active regions and extending in the first horizontal direction, the plurality of gate structures comprising
a first gate structure on the first main active region of a first active region,
a second gate structure on the second main active region of the first active region and the first main active region of a second active region,
a third gate structure on the third main active region of the first active region, and
a fourth gate structure on the fourth main active region of the first active region and the third main active region of the second active region.

15. The semiconductor device of claim 14, wherein the device isolation layer comprises a first portion between the first active region and the second active region and a second portion between the first main active region and the second main active region of each of the plurality of active regions, and wherein the device isolation layer is between the third main active region and the fourth main active region of each of the plurality of active regions, and
wherein each of the plurality of active regions has an H shape in a plan view.

16. The semiconductor device of claim 15, wherein the second gate structure comprises a first electrode region vertically overlapping the second main active region of the first active region, a second electrode region vertically overlapping the first main active region of the second active region, and an electrode connection portion between the first electrode region and the second electrode region, and
wherein the electrode connection portion vertically overlaps the first portion of the device isolation layer.

17. The semiconductor device of claim 16, wherein the first gate structure and the second gate structure are, on the second portion of the device isolation layer, apart from each other in the first horizontal direction.

18. The semiconductor device of claim 14, comprising a cell array region on the substrate,
wherein the cell array region comprises a plurality of word lines spaced apart from each other in a vertical direction, a plurality of channels passing through the plurality of word lines and extending in the vertical direction, and a cell contact connected to one of the plurality of word lines, and
wherein the cell contact is electrically connected to one of the plurality of active regions.

19. The semiconductor device of claim 18, wherein the cell array region comprises a plurality of memory blocks,
wherein the first main active region of the first active region is electrically connected to a first word line included in a first memory block from among the plurality of memory blocks,
wherein the second main active region of the first active region is electrically connected to a first word line included in a second memory block from among the plurality of memory blocks,
wherein the third main active region of the first active region is electrically connected to a first word line included in a third memory block from among the plurality of memory blocks,
wherein the fourth main active region of the first active region is electrically connected to a first word line included in a fourth memory block from among the plurality of memory blocks,
wherein the first main active region of the second active region is electrically connected to a second word line included in the second memory block, and
wherein the third main active region of the second active region is electrically connected to a second word line included in the fourth memory block.

20. A semiconductor device comprising:
a substrate comprising a plurality of active regions, wherein each of the plurality of active regions comprises:
a central region;
a first main active region and a second main active region extending from the central region and spaced apart from each other in a first horizontal direction; and
a third main active region and a fourth main active region extending from the central region and spaced apart from the first main active region and the second main active region in a second horizontal direction;
a device isolation layer on the substrate and defining the plurality of active regions, wherein the device isolation layer comprises a first portion between two adjacent active regions from among the plurality of active regions and a second portion between the first main active region and the second main active region of each of the plurality of active regions, wherein the device isolation layer is between the third main active region and the fourth main active region of each of the plurality of active regions;
a plurality of gate structures overlapping portions of two adjacent active regions from among the plurality of active regions and extending in the first horizontal direction, wherein the plurality of gate structures comprise
a first gate structure on the first main active region of a first active region,
a second gate structure on the second main active region of the first active region and the first main active region of a second active region,
a third gate structure on the third main active region of the first active region, and
a fourth gate structure on the fourth main active region of the first active region and the third main active region of the second active region; and
a drain contact on the central region and surrounded by the first to fourth gate structures in a plan view.
